(19) United States
(12) Patent Application Publication
(10) Pub. No.: US 2025/0149420 A1
(43) Pub. Date: May 8, 2025

(54) SEMICONDUCTOR PACKAGE WITH AT LEAST ONE PRE-MADE CONDUCTIVE UNIT AND PANEL-LEVEL METHODS OF MAKING THEREOF

(71) Applicant: PEP INNOVATION PTE. LTD., Singapore (SG)

(72) Inventor: Hwee Seng Chew, Singapore (SG)

(21) Appl. No.: 18/905,980

(22) Filed: Oct. 3, 2024

(30) Foreign Application Priority Data
Nov. 2, 2023 (SG) 10202303101X

(51) Int. Cl. H01L 23/498; H01L 23/00; H01L 23/31; H01L 25/065

(52) U.S. Cl. CPC H01L 23/49816; H01L 23/3121; H01L 23/49827; H01L 23/49838; H01L 24/16; H01L 24/05; H01L 24/08; H01L 25/0655; H01L 2224/05567; H01L 2224/08258; H01L 2224/16113; H01L 2224/16245; H01L 2924/3511

(57) ABSTRACT

Disclosed are a semiconductor package made from the first and second panel-level methods with at least one pre-made conductive unit. The semiconductor package includes one or more semiconductor dies, a molding layer for encapsulating the one or more semiconductor dies; at least one pre-made conductive unit prepared from a molded conductive substrate; a front build-up layer electrically coupled to the semiconductor dies and the at least one pre-made conductive unit; and an external connection layer electrically coupled to the front build-up layer. The semiconductor dies and pre-made conductive unit may be arranged in either a side-by-side configuration or a vertical configuration. The present application further discloses panel-level methods of making the semiconductor package with the at least one pre-made conductive unit. The present application further relates to several methods of preparing the at least one pre-made conductive unit.

### CROSS-REFERENCE TO RELATED APPLICATIONS

This application claims priority to Singapore Application No. 10202303101X, filed Nov. 2, 2023 and entitled “Cavity Substrates for Panel Level Chip Packaging and the Method of Fabrication”, which is incorporated herein by reference in its entirety.

### TECHNICAL FIELD

The present application relates to a semiconductor package with a pre-made conductive unit. The present application also relates to panel-level methods of making the semiconductor package with the pre-made conductive unit. The present application further relates to several methods of preparing the pre-made conductive unit.

Nowadays, vertical electrical connections are commonly formed during the processes of making semiconductor packages such as an on-site metal plating process for forming multi-layer build-up connections in a small scale. However, these traditional methods would cause serious warpage issues on a panel-level process in a large scale. In addition, the traditional on-site metal plating process is also slow in forming the connections.

Therefore, the present application discloses several panel-level methods to solve the warpage issues when making semiconductor packages in a large panel-level scale; and meanwhile the panel-level methods can be conducted in a faster manner for enhancing productivity of the packaging.

### SUMMARY

As a first aspect, the present application discloses a first panel-level method of forming a semiconductor package. The first panel-level method includes providing at least one semiconductor die and a plurality of pre-made conductive units onto a first carrier to their pre-determined positions respectively, and the pre-made conductive units are prepared from a molded conductive substrate; forming a molding layer for capsulating the at least one semiconductor die and the plurality of pre-made conductive units to constitute a reconstructed panel; transferring the reconstructed panel onto a second carrier; forming a front build-up layer on an active surface of the at least one semiconductor die; forming an external connection layer electrically coupled to the front build-up layer; and singulating the reconstructed panel, the front build-up layer and the external connection into the semiconductor package. The at least one semiconductor die and the plurality of pre-made conductive units are configured to be electrically coupled to the external connection layer through the front build-up layer. In particular, the semiconductor dies and the pre-made conductive unit are arranged in a side-by-side configuration in the reconstructed panel.

As a second aspect, the present application discloses a second panel-level method of forming a semiconductor package. The second panel-level method includes bonding a plurality of semiconductor dies onto a first carrier to their pre-determined positions respectively; forming a molding layer for encapsulating the plurality of semiconductor dies to constitute a reconstructed panel; transferring the reconstructed panel onto a second carrier; forming a front build-up layer on an active surface of the plurality of semiconductor dies; forming an interposer layer onto the front build-up layer, and the interposer layer comprises pre-made conductive units; and the pre-made conductive units are prepared from a molded conductive substrate; forming an external connection layer to the interposer layer; and singulating the reconstructed panel, the front build-up layer, the interposer layer and the external connection layer into the semiconductor package. The semiconductor dies are configured to be electrically coupled to the external connection layer through the front build-up layer and the interposer layer. In particular, the semiconductor dies and the pre-made conductive unit are arranged in a vertical configuration in the reconstructed panel and the interposer layer respectively.

The first and second panel-level methods also involve several methods of preparing the pre-made conductive unit. A first method of preparing the pre-made conductive unit includes mounting the molded conductive substrate onto the first carrier; and then removing insulating portions from the molded conductive substrate on the first carrier. Accordingly, the conductive portions of the molded conductive substrate are left as the pre-made conductive units individually. A second method of preparing the pre-made conductive unit includes removing insulating portions from the molded conductive substrate, and conductive portions of the molded conductive substrate are left as the pre-made conductive units individually; and then bonding the pre-made conductive units onto the first carrier to their pre-determined positions respectively.

As a third aspect, the present application discloses a semiconductor package made from the first and second panel-level methods with at least one pre-made conductive unit. The semiconductor package includes at least one semiconductor die; a molding layer for encapsulating the at least one semiconductor die; at least one pre-made conductive unit prepared from a molded conductive substrate; a front build-up layer electrically coupled to the at least one semiconductor die and the at least one pre-made conductive unit; and an external connection layer electrically coupled to the front build-up layer.

### BRIEF DESCRIPTION OF THE DRAWINGS

The accompanying figures (FIGS.) illustrate embodiments and serve to explain principles of the disclosed embodiments. It is to be understood, however, that these figures are presented for purposes of illustration only, and not for defining limits of relevant applications.

FIG. 1 illustrates a flow chart of a panel-level method S10 of making semiconductor packages according to an exemplary embodiment of the present disclosure.

FIGS. 2a to 2g illustrate a first embodiment of Steps S11 and S12 of the panel-level method S10.

FIGS. 3a to 3f illustrate a second embodiment of Steps S11 and S12 of the panel-level method S10.

FIGS. 4a to 4d illustrate a third embodiment of Steps S11 and S12 of the panel-level method S10.

FIGS. 5a & 5b illustrate Step S13 of the panel-level method S10.

FIG. 6 illustrates Step S14 of the panel-level method S10.

FIGS. 7a to 7c illustrate Step S15 of the panel-level method S10.

FIGS. 8 and 9 illustrate Step S16 of the panel-level method S10.

FIGS. 10a and 10b illustrate Step S17 of the panel-level method S10.

FIG. 11 illustrates Step S18 of the panel-level method S10.

FIG. 12 illustrates Step S19 of the panel-level method S10.

FIGS. 13a to 13e illustrate various embodiments of the semiconductor packages (SCM) obtained from the panel-level method S10.

FIGS. 14 to 17 illustrate a variation to the panel-level method S10.

FIGS. 18a to 18c illustrate various embodiments of the semiconductor packages (SCM) obtained from the variation in FIGS. 14 to 17.

FIGS. 19a to 19c illustrate a variation to the first embodiment of Steps S11 and S12 of the panel-level method S10 for MCM.

FIGS. 20a to 20c illustrate a variation to the second embodiment of Steps S11 and S12 of the panel-level method S10 for MCM.

FIGS. 21a to 21c illustrate a variation to the third embodiment of Steps S11 and S12 of the panel-level method S10 for MCM.

FIGS. 22a and 22b illustrate Step S13 of the panel-level method S10.

FIG. 23 illustrates Step S14 of the panel-level method S10.

FIG. 24 illustrates Step S15 of the panel-level method S10.

FIGS. 25 and 26 illustrate Step S16 of the panel-level method S10.

FIGS. 27a and 27b illustrate Step S17 of the panel-level method S10.

FIG. 28 illustrates Step S18 and Step 19 of the panel-level method S10.

FIGS. 29a to 29e illustrate various embodiments of the semiconductor packages (MCM) obtained from the panel-level method S10.

FIGS. 30 to 33 illustrate a variation to the panel-level method S10.

FIGS. 34a to 34c illustrate various embodiments of the semiconductor packages (MCM) obtained from the variation in FIGS. 30 to 33.

FIG. 35 illustrates another variation to Step S12 to the panel-level method S10.

FIGS. 36a to 36c illustrate various embodiment of the semiconductor packages (MCM) obtained from the variation in FIG. 35.

FIGS. 37a to 37d illustrate various embodiment of the semiconductor packages (MCM) obtained from the panel-level method S10.

FIG. 38 illustrates a flow chart of another panel-level method S20 of making semiconductor packages according to an exemplary embodiment of the present disclosure.

FIGS. 39a to 39i illustrate schematic diagrams of the panel-level method S20.

FIGS. 40a and 40b illustrate two embodiments of the semiconductor packages (MCM) obtained from the FIGS. 39a to 39i.

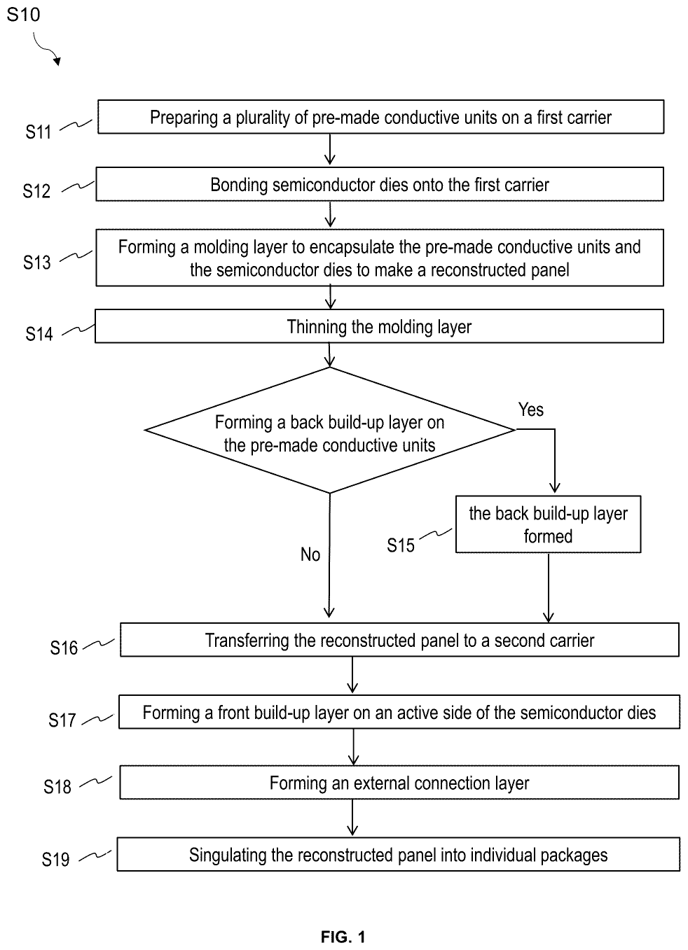

FIG. 1 illustrates a flow chart of a panel-level method S10 of making semiconductor packages according to an exemplary embodiment of the present disclosure. The panel-level method S10 includes Steps S11 to S19.

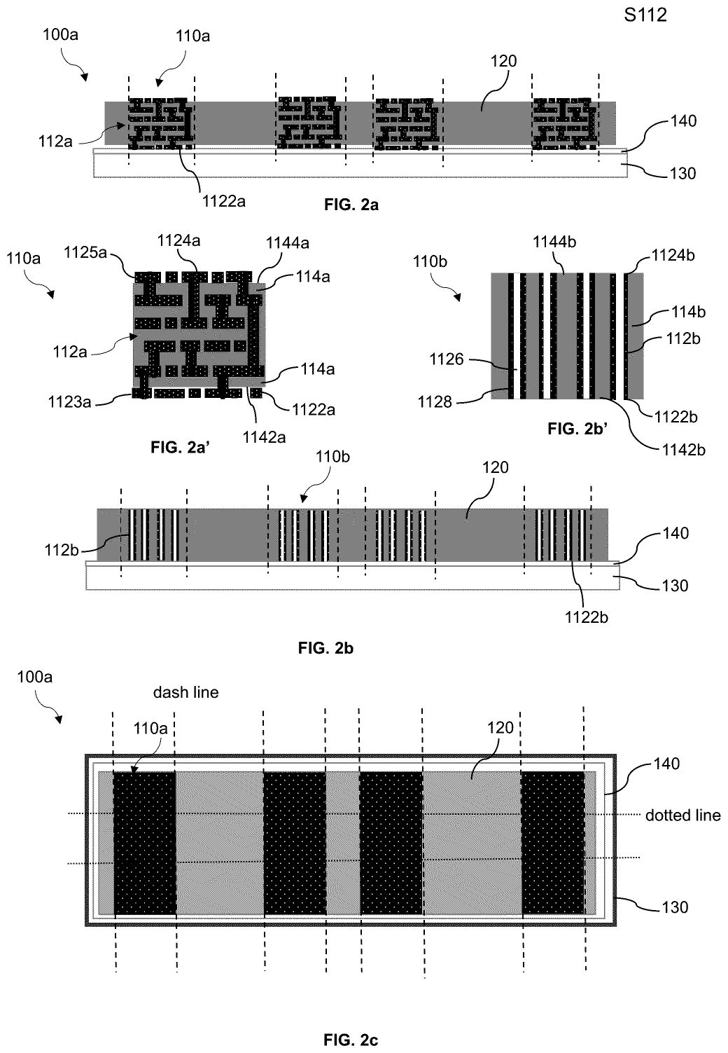

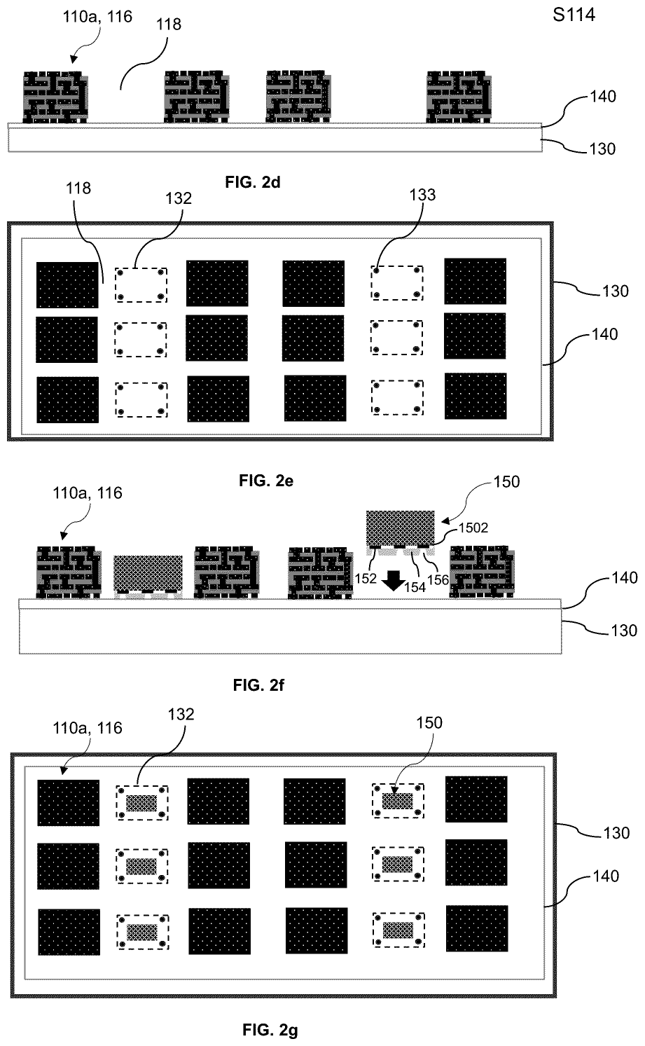

FIGS. 2a to 4d illustrates three embodiments for Steps of Steps S11 and S12 of the panel-level method S10. FIGS. 2a to 2g illustrates a first embodiment where Step S11 includes a first sub-step S112, i.e., mounting a molded conductive substrate 100 onto a first carrier 130. Optionally, a first heat release tape 140 may be applied between the molded conductive substrate 100 and the first carrier 130 for securing the molded conductive substrate 100 onto the first carrier 130 at an ambient temperature. The molded conductive substrate 100 has a conductive portion 110 for electrical conductance through the molded conductive substrate 100 along a thickness profile. The molded conductive substrate 100 may further have an insulating portion 120 for holding the molded conductive substrate 100 as an integrated piece when the molded conductive substrate 100 is mounted onto the first carrier 130. The insulating portion 120 may be made of any electrically insulating materials such as molding compounds. The conductive portion 110 may further includes conductive component 112 and insulating component 114.

As an embodiment, FIG. 2a shows in a cross-sectional view that the molded conductive substrate 100 may be a Molded Interconnect Substrate (MIS) 100a. The molded interconnect substrate (MIS) 100a has first conductive portions 110a (as one type of the conductive portion 110) separated by insulating portions 120; and the insulating portion 120 can be removed along the dash lines. FIG. 2a′ shows a magnified cross-sectional view of the first conductive portion 110a freestanding after the insulating portion 120 is removed. Accordingly, the freestanding first conductive portion 110a may function as one form of an individual pre-made conductive unit 116. The first conductive portion 110a includes multiple routing layers 112a interconnected as one type of the conductive component 112 for electrical conductance along the thickness profile between a first routing layer 1122a and a second routing layer 1124a. The first conductive portion 110a further includes an insulating component 114a such as molding compounds for encapsulating the multiple routing layers 112a. The insulating component 114a may be a part of the electrically insulating materials of the insulating portion 120 extending into the first conductive portion 110a. However, the first routing layer 1122a and the second routing layer 1124a are not encapsulated in the insulating component 114a. In other words, a first side 1123a of the first routing layer 1122a for defining a first thickness of the first routing layer 1122a is exposed from a first surface 1142a of the insulating component 114a; and similarly, a second side 1125a of the second routing layer 1124a for defining a second thickness of the second routing layer 1124a is also exposed from a second surface 1144a of the insulating component 114a. The first thickness of the first routing layer 1122a and the second thickness of the second routing layer 1124a may be same or different.

As another embodiment, FIG. 2b shows in a cross-sectional view that the molded conductive substrate 100 may be a Molded Via Substrate (MVS) 100b. Similarly, the molded via substrate (MVS) 100b also has second conductive portions 110b (as another type of the conductive portion 110) separated by the insulating portions 120; and the insulating portion 120 can be removed along the dash lines. FIG. 2b′ shows a magnified cross-sectional view of the second conductive portion 110b after the insulating portion 120 is removed. Accordingly, the second conductive portion 110b may function as another form of the individual pre-made conductive unit 116. The second conductive portion 110b includes a conductive component of one or more conductive through-vias 112b as another type of the conductive component 112 for electrical conductance along the thickness profile between a through-via front surface 1122b and a through-via back surface 1124b. The second conductive portion 110b also further includes an insulating component 114b such as molding compounds for encapsulating the conductive through-vias 112b. The insulating component 114a may be a part of the electrically insulating materials of the insulating portion 120 extending into the second conductive portion 110b. In particular, the conductive through-vias 112b extends through the insulating component 114b; and the through-via front surface 1122b and the through-via back surface 1124b of the conductive through-vias 112b are co-planar with a first surface 1142b and a second surface 1144b of the insulating component 114b respectively.

The molded via substrate (MVS) 100b may be made by first forming one or more hollow vias 1126 through the insulating component 114b in the second conductive portion 110b, and then filling the hollow vias 1126 fully or partially with any conductive materials such as Copper. Preferably, the hollow vias 1126 are partially filled to save the conductive materials filled in the hollow vias 1126 and accordingly to reduce weight of the second conductive portion 110b for further eliminating potential warpage in subsequent processes. It is shown in FIG. 2b that the conductive materials are adhered to sidewalls 1128 of the hollow vias 1126 only, leaving the hollow vias 1126 partially unfilled in a central area. But the filled conductive materials are sufficient to form a continuous conductive path along the sidewalls 1128 between the through-via front surface 1122b and the through-via back surface 1124b of the conductive through-vias 112b. It is understood that the molded interconnect substrate (MIS) 100a and the molded via substrate (MVS) 100b are embodiments only for the molded conductive substrate 100; and other forms of the molded conductive substrate 100 are also included within the scope of the present application. Accordingly, the first conductive portion 110a and the second conductive portion 110b are embodiments only for the conductive portion 110 (and the pre-made conductive unit 116 after separation); and other forms of the conductive portion 110 (and the pre-made conductive unit 116 after separation) are also included within the scope of the present application. For easy illustration, subsequent steps of the S10 would be shown with the molded interconnect substrate (MIS) 100a only as the molded conductive substrate 100 and the first conductive portion 110a as the conductive portion 110 (and the pre-made conductive unit 116 after separation); but it is understood that the following description would also be applicable to other forms of the molded conductive substrate 100 and conductive portion 110, including the molded via substrate (MVS) 100b and the second conductive portion 110b.

FIG. 2c shows a top view that the insulating portion 120 is removable as indicated by the dash lines along a width profile; and then the first conductive portion 110a of the molded interconnect substrate (MIS) 100a may be dividable as indicated by the dotted lines along a length profile. As a result, the pre-made conductive unit 116 are formed from the first conductive portion 110a circumscribed by the dash lines and the dotted lines. FIG. 2d shows a cross-sectional view that the Step S11 includes a second sub-step S114, i.e., removing the insulating portion 120 from the molded interconnect substrate (MIS) 100a (and maybe dividing the first conductive portion 110a) for forming the pre-made conductive unit 116; and accordingly gaps 118 are formed at original positions of the insulating portion 120 between the first conductive portion 110a. In contrast to the traditional vertical electrical connections made on-site such as by the on-site metal plating process, the pre-made conductive unit 116 are made prior to panel-level packaging processes such as bonding semiconductor dies 150 to the first carrier 130; and thus, S10 of the present application can reduce significantly or even eliminate the serious warpage issues occurring in the traditional packaging methods.

FIG. 2e shows a top view that the first carrier 130 has die bonding regions 132 (as indicated by the dashed rectangles) within the gap 118 for accommodating the semiconductor dies 150; and primary markings 133 within the die bonding region 132 for guiding the semiconductor dies 150 to be bonded to their respective pre-determined positions within the die bonding region 132. Although it is shown that the die bonding region 132 has four primary markings 133 at four corners of the die bonding region 132 respectively, it is understood that other numbers of the primary markings 133 and their distributions are also within the scope of the present application.

FIG. 2f shows a cross-sectional view of Step S12, i.e., bonding the semiconductor dies 150 within their respective die bonding regions 132. The semiconductor die 150 has one or more contact pads 152 at its active surface 1502 for leading out functional circuits of the semiconductor die 150, a protective layer 154 formed on the active surface 1502 for protecting the functional circuits, and one or more pre-vias 156 in the protective layer 154 for exposing the contact pads 152 from the protective layer 154. The semiconductor dies 150 are bonded in a face-down manner so that the protective layer 154 is in contact with the first heat release tape 140 or the first carrier 130. FIG. 2g shows a top view of the semiconductor dies 150 bonded onto the first carrier 130 within their respective die bonding regions 132. Preferably, the primary markings 133 are not covered by the semiconductor die 150 for performing a post-bonding inspection to check whether the semiconductor dies 150 are bonded to the pre-determined positions within their respective dic bonding regions 132.

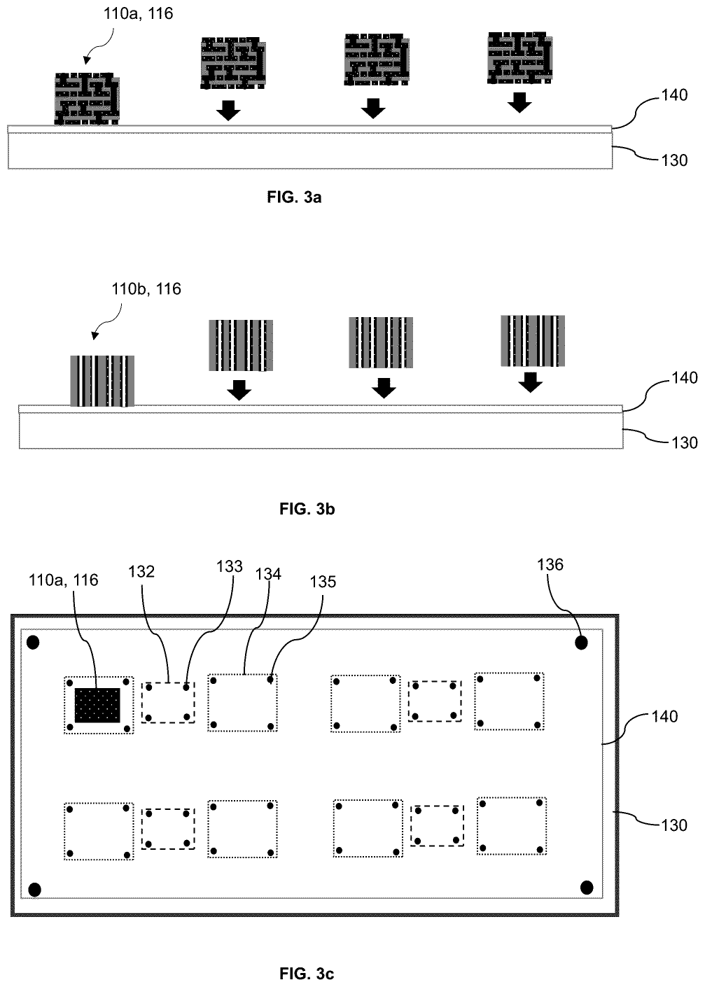

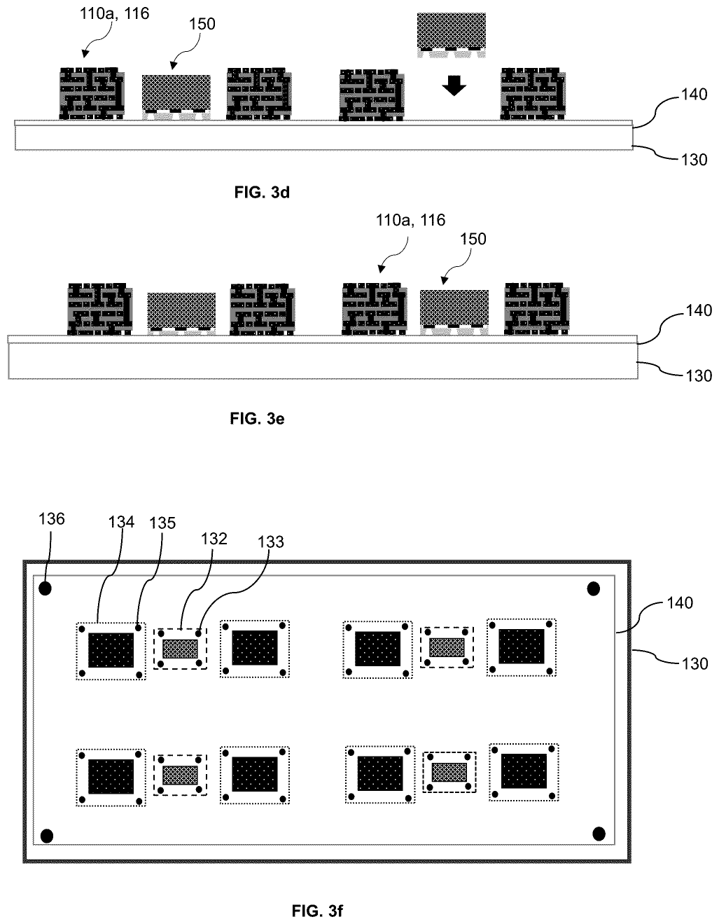

Alternatively, in contrast to the first embodiment where the insulating portion 120 are removed after mounting the molded conductive substrate 100 onto the first carrier 130, the insulating portion 120 are removed elsewhere without mounting the molded conductive substrate 100 onto the first carrier 130; and the pre-made conductive unit 116 are therefore made as the freestanding conductive portion 110. Then, the pre-made conductive unit 116 is bonded onto the first carrier 130 at its per-determined position. Following this alternative method, FIGS. 3a to 3f illustrates a second embodiment of Steps S11 and S12 of the panel-level method S10. FIGS. 3a and 3b show cross-sectional views of Step S11 by bonding the pre-made conductive unit 116 (in the forms of the first conductive portion 110a and the second conductive portion 110b in FIGS. 3a and 3b respectively) onto the first carrier 130. In addition to the die bonding region 132 and the primary markings 133 for the semiconductor die 150, FIG. 3c shows a top view that the first carrier 130 has unit bonding regions 134 (as indicated by the dotted rectangles) for accommodating the pre-made conductive unit 116; and secondary markings 135 within the unit bonding region 134 for guiding the pre-made conductive unit 116 to be bonded to their pre-determined positions. Although four secondary markings 135 are shown to be at four corners of the unit bonding region 134 respectively, it is understood that other numbers of the secondary markings 135 and their distributions are also within the scope of the present application. Preferably, the secondary markings 135 are not covered by the pre-made conductive unit 116 for performing a post-bonding inspection to check whether the pre-made conductive unit 116 are bonded to their respective pre-determined positions. Alternatively, the pre-made conductive unit 116 may be guided by the primary markings 133 if the secondary markings 135 do not exist on the first carrier 130. Moreover, the first carrier 130 may also have fiducials 136 for locating the die bonding region 132 and the unit bonding region 134 on the first carrier 130.

FIG. 3d shows for the second embodiment a cross-sectional view of Step 12, i.e., bonding the semiconductor dies 150 into their respective die bonding regions 132 on the first carrier 130. FIGS. 3c and 3f show a cross-sectional view and a top view that the pre-made conductive unit 116 and the semiconductor die 150 are bonded onto the first carrier 130 according to a packaging design. Alternative to be guided by the primary markings 133, the semiconductor die 150 may be guided by the secondary markings 135. If precisely bonded, the semiconductor die 150 and the pre-made conductive unit 116 can be easily located on the first carrier 130 by referring to the primary markings 133 and/or the secondary markings 135 both of which can be further located by referring to the fiducials 136.

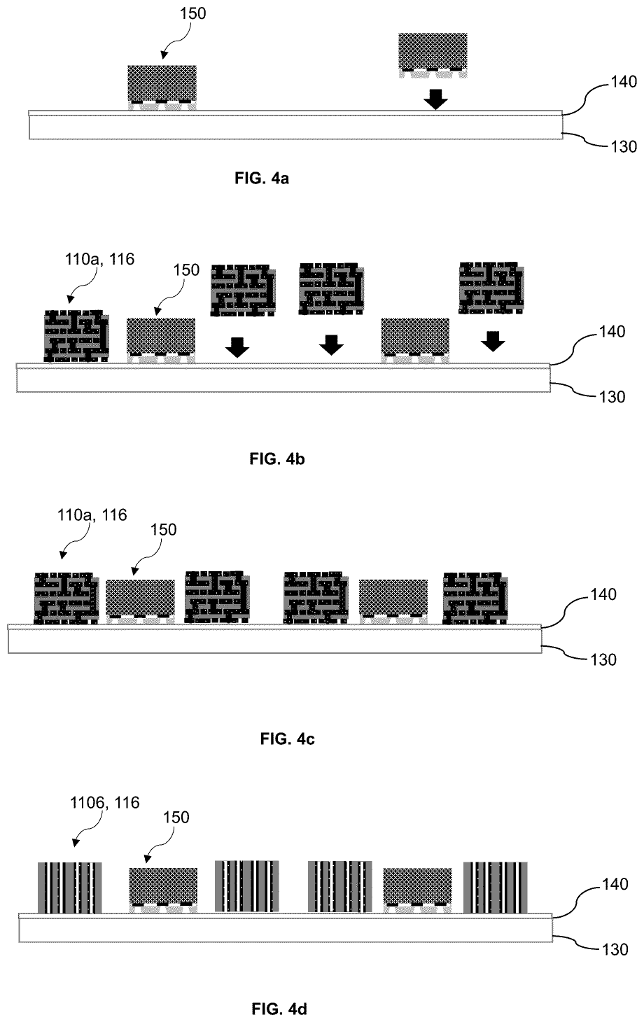

Following the alternative method above, FIGS. 4a to 4c illustrates a third embodiment of Steps S11 and S12 of the panel-level method S10, as described above for the second embodiment. However, in the third embodiment, Step 11 and Step 12 are conducted in a reverse sequence. FIG. 4a shows that Step S12 is first performed by bonding the semiconductor die 150 onto the first carrier 130. Then, Step S11 is performed by bonding the pre-made conductive unit 116 (in the form of the first conductive portion 110a) onto the first carrier 130 as shown in FIG. 4b. Finally, FIG. 4c shows a cross-sectional view that the pre-made conductive unit 116 and the semiconductor dies 150 are also bonded to their respective pre-determined positions onto the first carrier 130. FIG. 4d shows a similar cross-sectional view to FIG. 4c except that the pre-made conductive unit 116 is bonded in the form of the second conductive portion 110b. Therefore, the third embodiment would also achieve the same packaging design as shown in FIG. 3f; and if precisely bonded, the semiconductor die 150 and the pre-made conductive unit 116 can be easily located on the first carrier 130 by referring to the primary markings 133 and/or the secondary markings 135 both of which can be further located by referring to the fiducials 136.

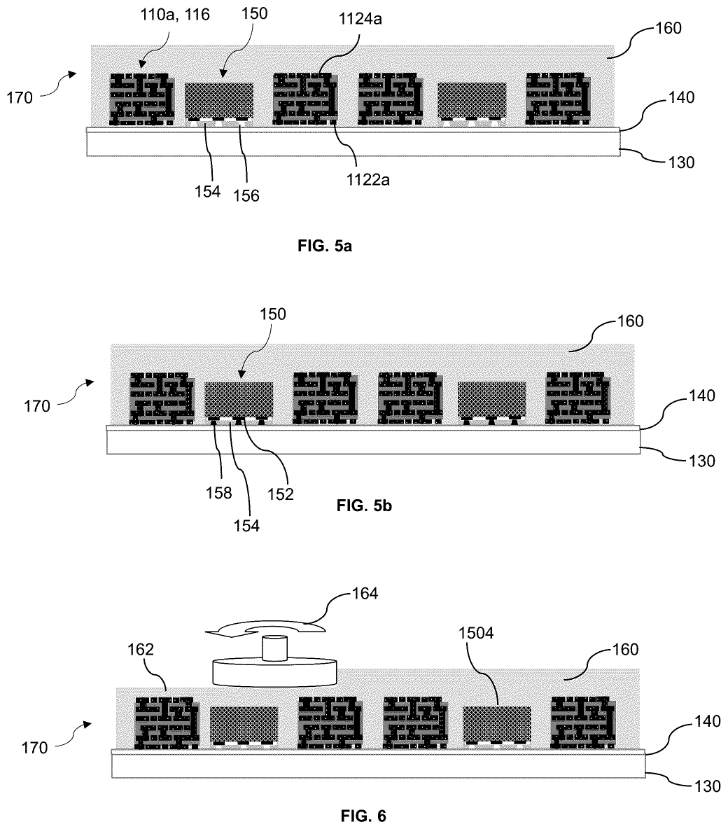

FIGS. 5a & 5b illustrates Step S13 of the panel-level method S10, i.e., forming a molding layer 160 for encapsulating the pre-made conductive unit 116 (in the form of the first conductive portion 110a) and the semiconductor dies 150 to make a reconstructed panel 170. In particular, the first routing layer 1122a and the second routing layer 1124a of the first conductive portion 110a are encapsulated in the molding layer 160. The molding layer 160 may be performed by any know molding technologies such as compression molding. FIG. 5a shows a cross-sectional view that the pre-vias 156 of the semiconductor die 150 are not filled before bonding the semiconductor die 150 onto the first carrier 130. Alternatively, as shown in FIG. 5b, the pre-vias 156 of the semiconductor die 150 may be filled with conductive materials before bonding the semiconductor die 150 onto the first carrier 130. Therefore, filled vias 158 are formed in the protective layer 154 and electrically coupled to the contact pads 152 for further leading out the functional circuits of the semiconductor die 150.

FIG. 6 illustrate Step S14 of the panel-level method S10, i.e., thinning the molding layer 160 by removing a portion of molding layer 160 from a back surface 1504 of the semiconductor die 150 by any known method such as a grinding apparatus 164. Step S14 is optionally performed when the molding layer 160 has a thickness more than the packaging design. In particular, a top portion 162 of the molding layer 160 still remains for encapsulating the pre-made conductive unit 116 and the semiconductor die 150 (including the back surface 1504 of the semiconductor die 150).

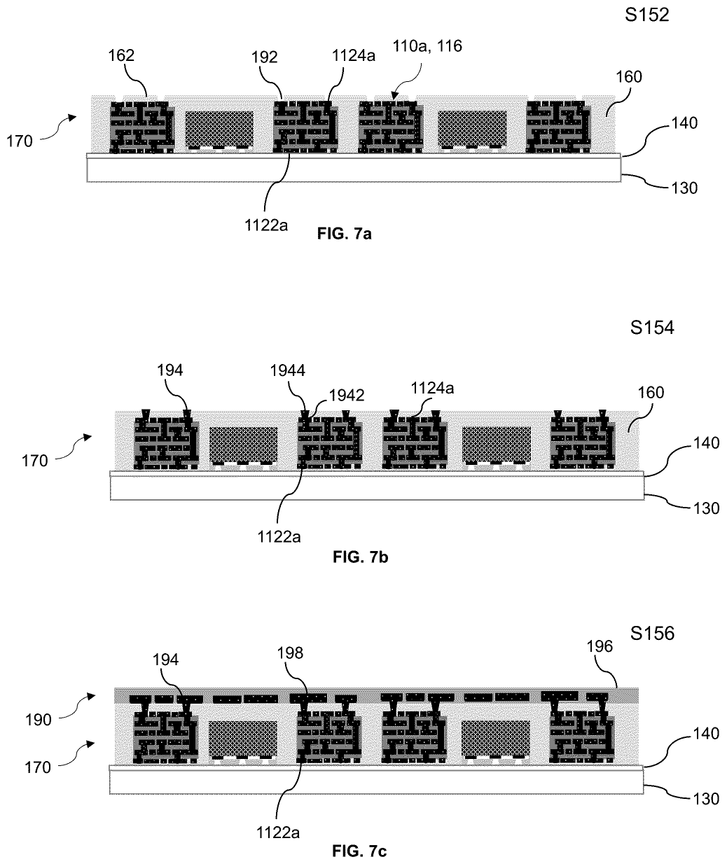

FIGS. 7a to 7c illustrate Step S15 of the panel-level method S10, i.e., forming a back build-up layer 190 on the pre-made conductive unit 116. FIG. 7a shows a first sub-step S152 of Step S15, i.e., forming back vias 192 in the top portion 162 of the molding layer 160 for exposing the second routing layer 1124a of the first conductive portion 110a. FIG. 7b shows a second sub-step S154 of Step S15, i.e., filling the back vias 192 with conductive materials to form back filled vias 194. The back filled vias 194 have a first via surface 1942 electrically coupled to the second routing layer 1124a and a second via surface 1944 exposed from the top portion 162 of the molding layer 160. FIG. 7c shows a third sub-step S156 of Step S15, i.e., forming back traces 198 electrically coupled to the back filled vias 194 and a back dielectric layer 196 encapsulating the back traces 198.

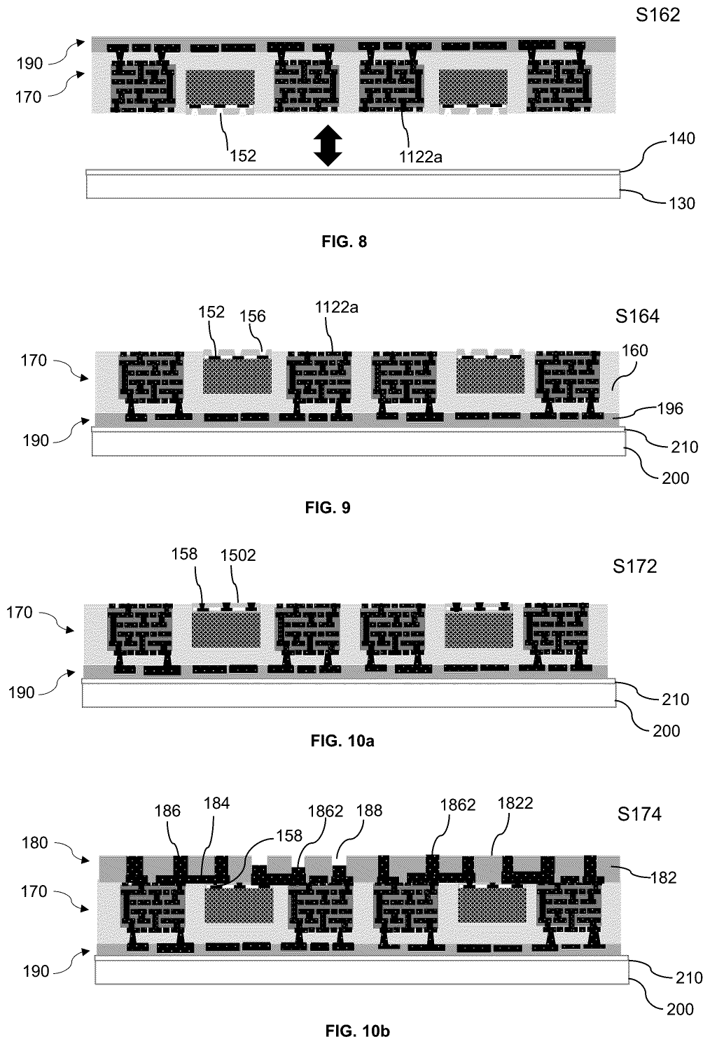

FIGS. 8 & 9 illustrate Step S16 of the panel-level method S10, i.e., transferring the reconstructed panel 170 with the back build-up layer 190 to a second carrier 200. FIG. 8 shows a first sub-step S162 of Step S16, i.e., separating the reconstructed panel 170 with the back build-up layer 190 from the first carrier 130 and the first heat release tape 140. It may be performed by heating the first heat release tape 140 to an elevated temperature since the first heat release tape 140 would lose adhesivity to the reconstructed panel 170 under the elevated temperature. FIG. 9 shows a second sub-step S164 of Step S16, i.e., mounting the reconstructed panel 170 with the back build-up layer 190 to the second carrier 200 in a flip manner, so that the back dielectric layer 196 is in contact with the second carrier 200; while the contact pads 152 (through the pre-vias 156) and the first routing layer 1122a of the first conductive portion 110a are exposed from the molding layer 160. Similarly, a second heat release tape 210 may be applied between the back build-up layer 190 and the second carrier 200 for securing the reconstructed panel 170 with the back build-up layer 190 onto the second carrier 200 at an ambient temperature.

FIGS. 10a & 10b illustrate Step S17 of the panel-level method S10, i.e., forming a front build-up layer 180 on the active surface 1502 of the semiconductor die 150 and the first routing layer 1122a of the first conductive portion 110a. FIG. 10a shows a first sub-step S172 of Step S17, i.e., filling the pre-vias 156 into the filled vias 158 with conductive materials if the pre-vias 156 have not been filled before bonding the semiconductor die 150 onto the first carrier 130 following FIG. 5a. The sub-step S172 can be skipped following FIG. 5b where the pre-vias 156 have been filled before bonding the semiconductor die 150 onto the first carrier 130. FIG. 10b shows a second sub-step S174 of Step S17, i.e., forming the front build-up layer 180 onto the active surface 1502 of the semiconductor die 150 and the first routing layer 1122a of the first conductive portion 110a. The front build-up layer 180 includes front traces 184 electrically coupled to the filled vias 158, front studs 186 electrically coupled to the front traces 184, and a front dielectric layer 182 encapsulating the front traces 184 and the front studs 186. The front stud 186 has a first stud surface 1862 exposed from the front dielectric layer 182. In one embodiment, the first stud surface 1862 is co-planar with a first dielectric surface 1822 of the front dielectric layer 182. In another embodiment, the first stud surface 1862 is exposed through a stud cavity 188 from the first dielectric surface 1822 of the front dielectric layer 182. The stud cavity 188 may have a cavity depth in a range of 1 to 15 micrometers (μm), or more particularly in a range of 1 to 5 micrometers (μm), in a range of 3 to 6 micrometers (μm), or in a range of 5 to 15 micrometers (μm).

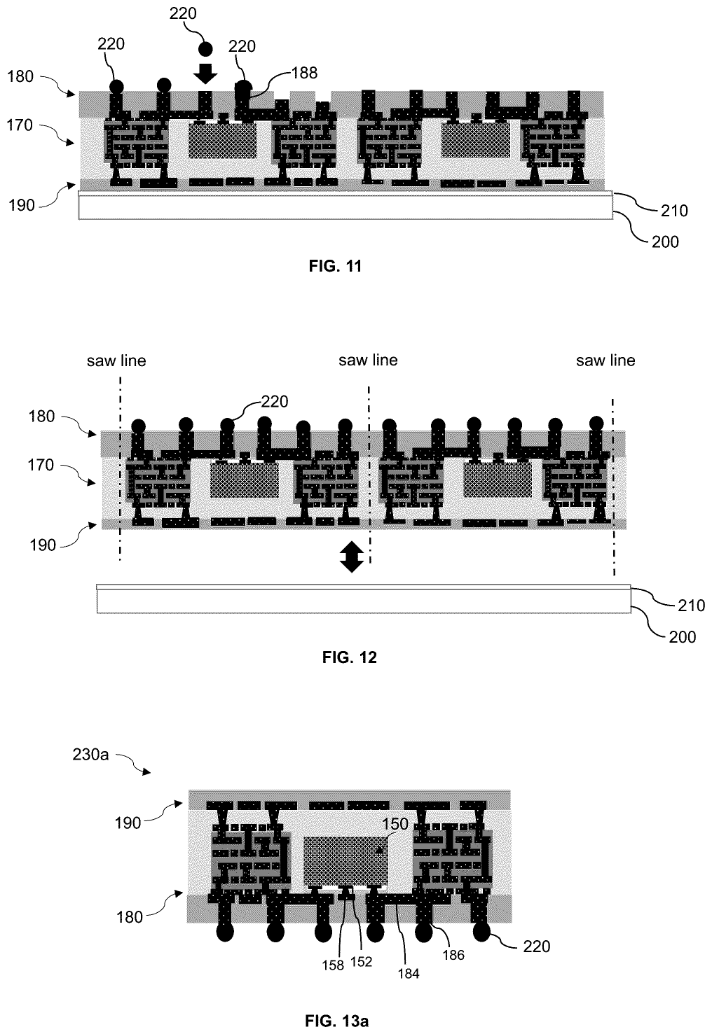

FIG. 11 illustrates Step S18 of the panel-level method S10, i.e., forming an external connection layer 220, such as solder balls. It is shown in a cross-sectional view that solder balls are dropped on and electrically coupled to the front studs 186 as the external connection layer 220. Preferably, the solder ball first melts and fuses into the stud cavity 188 and then is coupled to the front studs 186 for securing the solder ball in place during subsequent processes. It is understood that other forms of the external connection layer 220 are also within the scope of the present application such as Copper columns 322.

FIG. 12 illustrates Step S19 of the panel-level method S10, i.e., separating the reconstructed panel 170 with the front build-up layer 180 and the back build-up layer 190 from the second carrier 200 and the second heat release tape 210 and then singulating the reconstructed panel 170 with the front build-up layer 180 and the back build-up layer 190 into individual semiconductor packages 230 along saw lines (indicated as the dash lines).

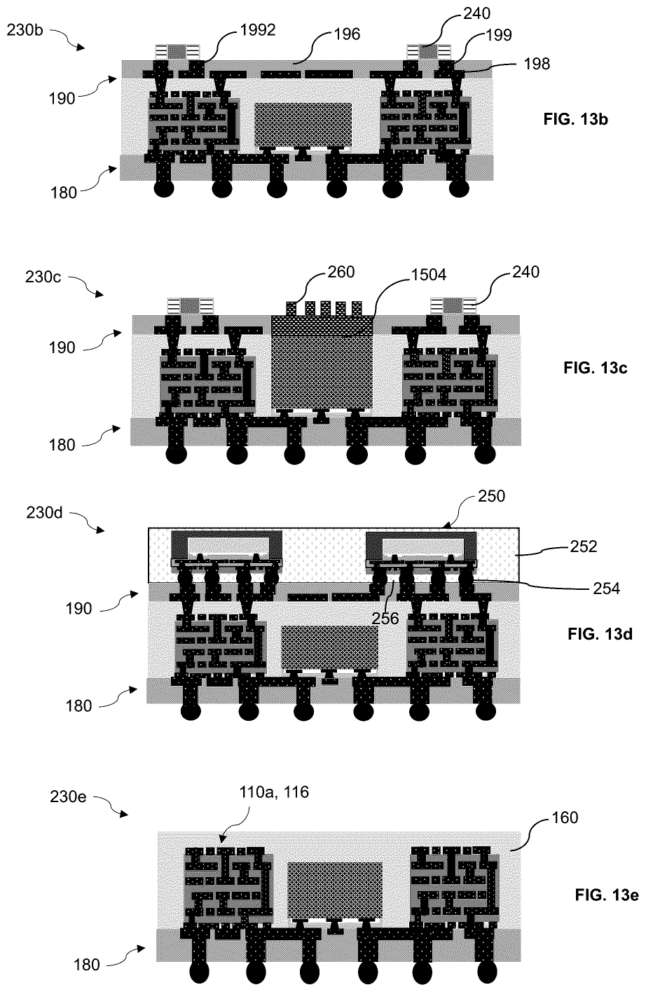

FIGS. 13a to 13e illustrate various embodiment of the semiconductor packages 230 (Single Chip Module (SCM)) obtained from the panel-level method S10. FIG. 13a shows a cross-sectional view of a semiconductor package 230a where the functional circuits of the semiconductor die 150 are led out electrically through the contact pads 152, the filled vias 158, the front traces 184 and the front studs 186 of the front build-up layer 180 and the external connection layer 220 such as solder balls. FIG. 13b shows a cross-sectional view of a semiconductor package 230b where the back build-up layer 190 further includes back studs back studs 199 coupled to the back traces 198. The back studs 199 has a second stud surface 1992 exposed from the back dielectric layer 196 so that passive electrical devices 240 (such as capacitors) can be mounted on and electrically coupled to the back build-up layer 190. FIG. 13c shows a cross-sectional view of a semiconductor package 230c where the back surface 1504 of the semiconductor die 150 is exposed from the molding layer 160; and a heat sink 260 can be mounted onto and in direct contact with the back surface 1504 of the semiconductor die 150 for enhancing heat dissipation. FIG. 13d shows a cross-sectional view of a semiconductor package 230d where top semiconductor packages 250 can be mounted on and electrically coupled to the back build-up layer 190 for forming a Package-on-Package (POP) configuration. Preferably, the top semiconductor packages 250 are encapsulated inside a package dielectric layer 252 which could meanwhile act as an underfill to protect an internal connection layer 254 such as solder balls. Compared with the traditional molding compounds such as Sumitomo G730, the package dielectric layer 252 has a smaller filler size so that the package dielectric layer 252 can go into an internal space 256 around the internal connection layer 254. Optionally, the filler size of the package dielectric layer 252 is less than 20 micrometers (μm); and preferably, the filler size of the package dielectric layer 252 is in a range of 10 to 20 micrometers (μm). FIG. 13e shows a cross-sectional view of a semiconductor package 230c without the back build-up layer 190; and the first conductive portion 110a as the pre-made conductive unit 116 are completely encapsulated inside the molding layer 160.

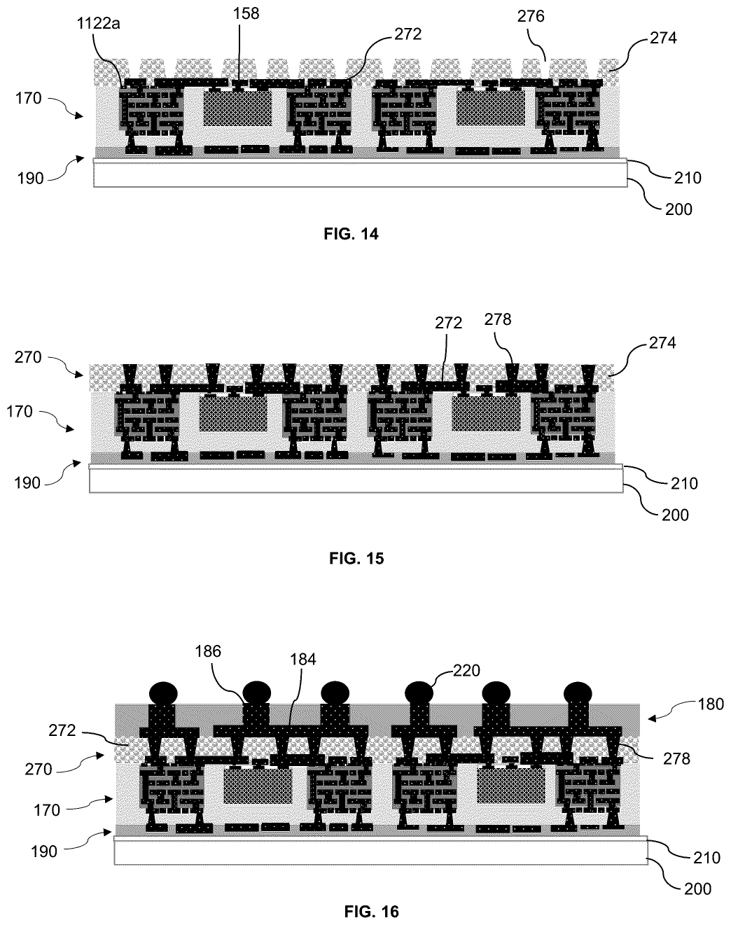

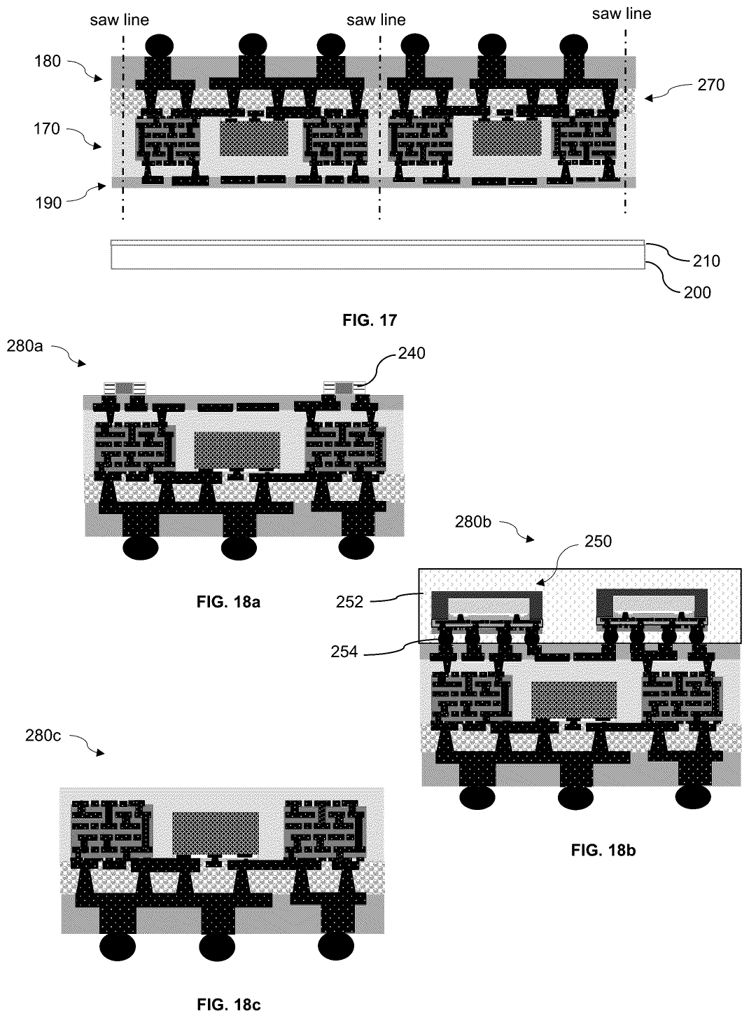

FIGS. 14 to 17 illustrate a variation to the panel-level method S10 by further including an additional build-up layer 270 on the active surface 1502 of the semiconductor die 150 and the first routing layer 1122a of the first conductive portion 110a. Following FIG. 10a, FIG. 14 shows a cross-sectional view that the additional build-up layer 270 include additional traces 272 electrically coupled to the filled vias 158 of the semiconductor die 150 and the first routing layer 1122a of the first conductive portion 110a (as the pre-made conductive unit 116); an additional dielectric layer 274 for encapsulating the additional traces 272, and additional vias 276 for exposing portions of the additional traces 272 from the additional dielectric layer 274. FIG. 15 shows that the additional vias 276 are filled with any conducting materials to form additional filled vias 278 electrically coupled to the additional traces 272. FIG. 16 shows that the front build-up layer 180 is formed on the additional build-up layer 270 with the front traces 184 electrically coupled to the additional filled vias 278; and then the external connection layer 220 such as solder balls is formed as described above. Similar to FIG. 12, FIG. 17 shows that the reconstructed panel 170 with the front build-up layer 180, the back build-up layer 190 and the additional build-up layer 270 is first separated from the second carrier 200 and second heat release tape 210; and then singulated into individual semiconductor packages 280 with one semiconductor die 150 (SCM).

FIGS. 18a to 18c illustrate various embodiments of the semiconductor packages 280 (SCM) obtained from the variation obtained from FIGS. 14 to 17. FIGS. 18a to 18c show cross-sectional views of semiconductor packages 280a, 280b and 280c which have similar structures to the semiconductor packages 230b, 230d and 230e respectively, except that the semiconductor packages 280a, 280b and the 280c have the additional build-up layer 270 sandwiched between the reconstructed panel 170 and the front build-up layer 180. The internal connection layer 254 in FIG. 18b is also used as the underfill as described above to protect the internal connection layer 254 such as solder balls.

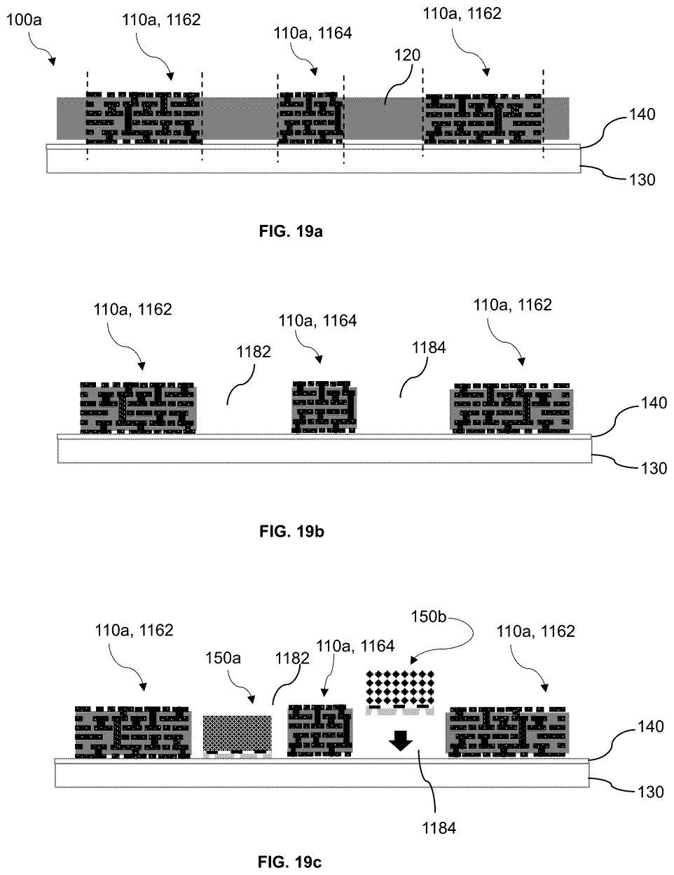

The following description shows a variation to the panel-level method S10 as described above for making Multiple-Chip-Module (MCM) which has two or more semiconductor dies 150. FIGS. 19a to 19c briefly illustrate a variation to the first embodiment of Steps S11 and S12 of the panel-level method S10 shown in FIGS. 2a to 2g. Similarly, FIG. 19a shows that the first conductive portion 110a as the pre-made conductive unit 116 is obtained by first mounting the molded interconnect substrate (MIS) 100a onto the first carrier 130 and the first heat release tape 140, and then removing the insulating portion 120 from the molded interconnect substrate (MIS) 100a along the dash lines. FIG. 19b shows that two types of the pre-made conductive unit 116 may be prepared from the first conductive portion 110a here, i.e., a first pre-made conductive unit 1162 and a second pre-made conductive unit 1164; and two types of the gap 118 may be formed here between the first pre-made conductive unit 1162 and the pre-made conductive unit second pre-made conductive unit 1164, i.e., a first gap 1182 and a second gap 1184 for accommodating two types of semiconductor dies 150, i.e., a first semiconductor die 150a and a second semiconductor die 150b. FIG. 19c shows that the first semiconductor die 150a and the second semiconductor die 150b are respectively bonded on the first carrier 130 and the first heat release tape 140 and within the first gap 1182 and the second gap 1184.

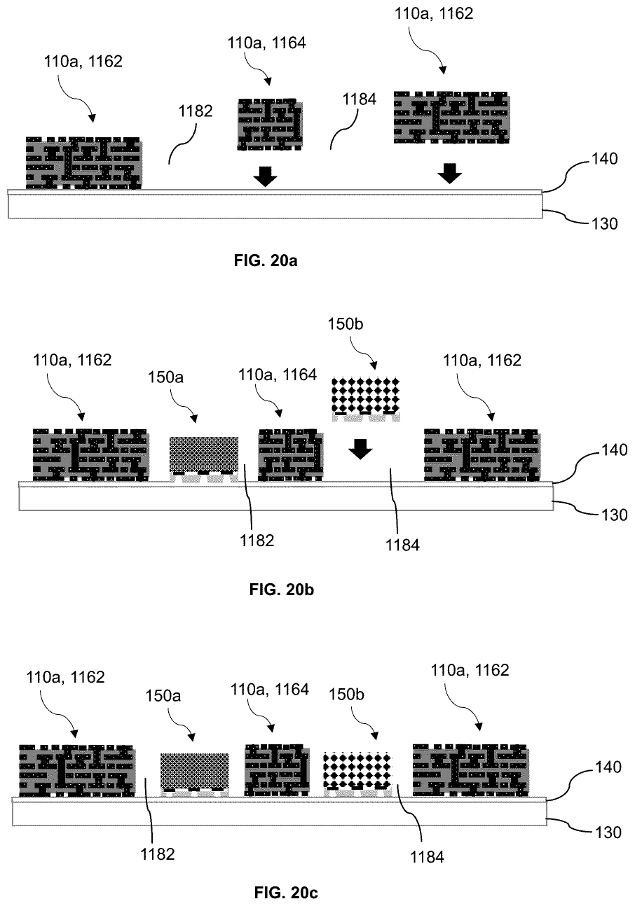

FIGS. 20a to 20c briefly illustrate a variation to the second embodiment of Steps S11 and S12 of the panel-level method S10 shown in FIGS. 3a to 3f. Similarly, FIG. 20a shows that the first pre-made conductive unit 1162 and the second pre-made conductive unit 1164 are bonded to the first carrier 130 and the first heat release tape 140 to their pre-determined positions respectively, with the first gap 1182 and the second gap 1184 therebetween. FIG. 20b shows that the first semiconductor die 150a and the second semiconductor die 150b are then bonded at their pre-determined positions within the first gap 1182 and the second gap 1184 respectively onto the first carrier 130. FIG. 20c shows that the Steps S11 and S12 are completed with the first semiconductor die 150a between the first pre-made conductive unit 1162 and the second pre-made conductive unit 1164 spaced by the first gap 1182 and the second semiconductor die 150b between the second pre-made conductive unit 1164 and the first pre-made conductive unit 1162 spaced by the second gap 1184.

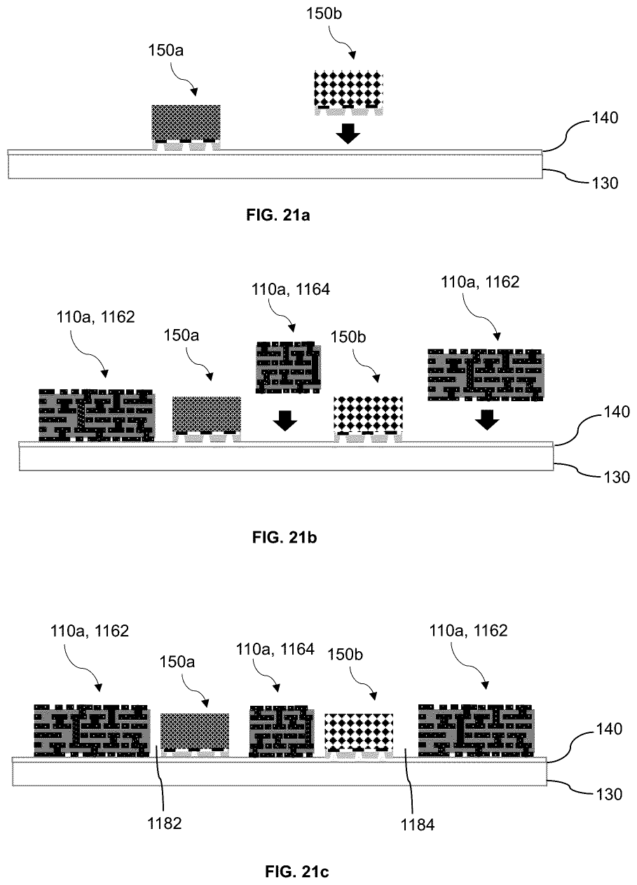

FIGS. 21a to 21c illustrate a variation to the third embodiment of Steps S11 and S12 of the panel-level method S10 shown in FIGS. 4a to 4d. Similarly, FIG. 21a shows that the first semiconductor die 150a and the second semiconductor die 150b are bonded to their pre-determined positions on the first carrier 130. FIG. 21b shows that the first pre-made conductive unit 1162 and the second pre-made conductive unit 1164 are then bonded to their pre-determined positions on the first carrier 130. FIG. 21c shows that Steps S11 and S12 are completed with the same package structure as shown in FIG. 20c.

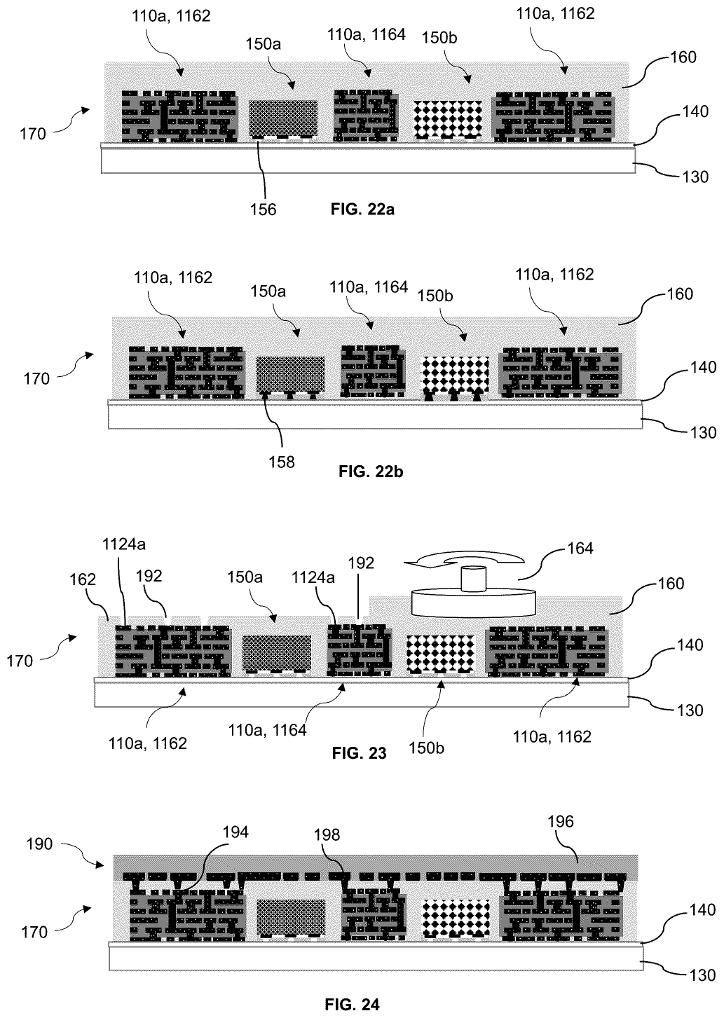

FIGS. 22a & 22b illustrate Step S13 of the panel-level method S10 for MCM. Similar to FIG. 5a, the molding layer 160 is formed for encapsulating the first pre-made conductive unit 1162, the second pre-made conductive unit 1164, the first semiconductor die 150a and the second semiconductor die 150b for forming the reconstructed panel 170. FIG. 22a shows a cross-sectional view that the pre-vias 156 is not filled before the bonding; while FIG. 22b shows a cross-sectional view that the pre-vias 156 is filled into the filled vias 158 before the bonding.

FIG. 23 illustrates Step S14 of the panel-level method S10 for MCM. Similar to FIG. 6, the top portion 162 is left after the grinding apparatus 164 is performed to the molding layer 160; and then the back vias 192 is formed in the top portion 162 for exposing the second routing layer 1124a of the first pre-made conductive unit 1162 and the second pre-made conductive unit 1164.

FIG. 24 illustrates Step S15 of the panel-level method S10 for MCM. Similar to FIG. 7c, the back vias 192 is filled with conductive materials into the back filled vias 194; and then the back dielectric layer 196 and the back traces 198 are formed to make up the back build-up layer 190.

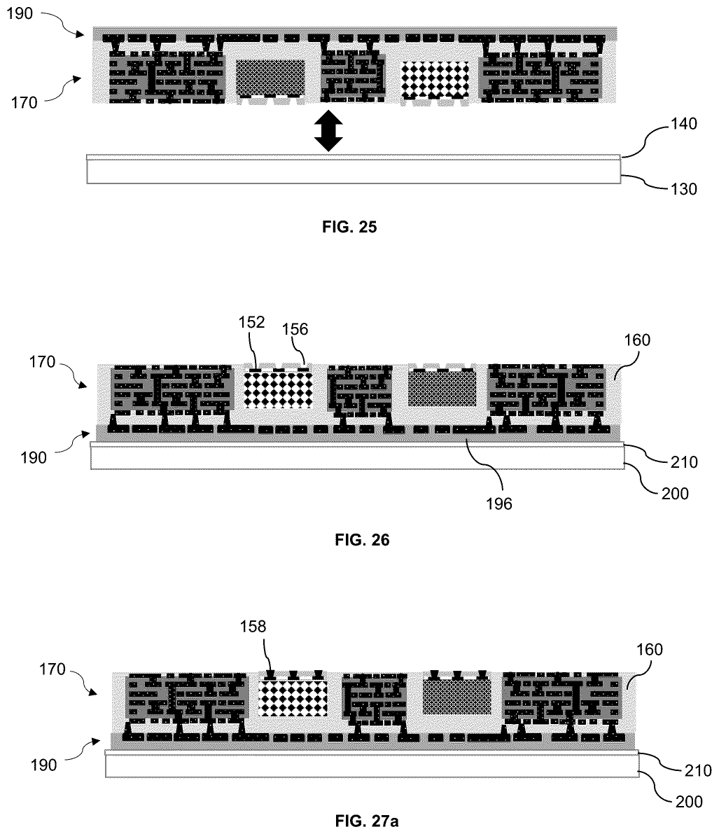

FIGS. 25 & 26 illustrate Step S16 of the panel-level method S10 for MCM. Similar to FIGS. 8 & 9, the reconstructed panel 170 with the back build-up layer 190 are separated from the first carrier 130 and the first heat release tape 140 under an elevated temperature; and then mounted onto the second carrier 200 and the second heat release tape 210 in the flip manner, with the back dielectric layer 196 of the back build-up layer 190 in contact with the second carrier 200 and the second heat release tape 210.

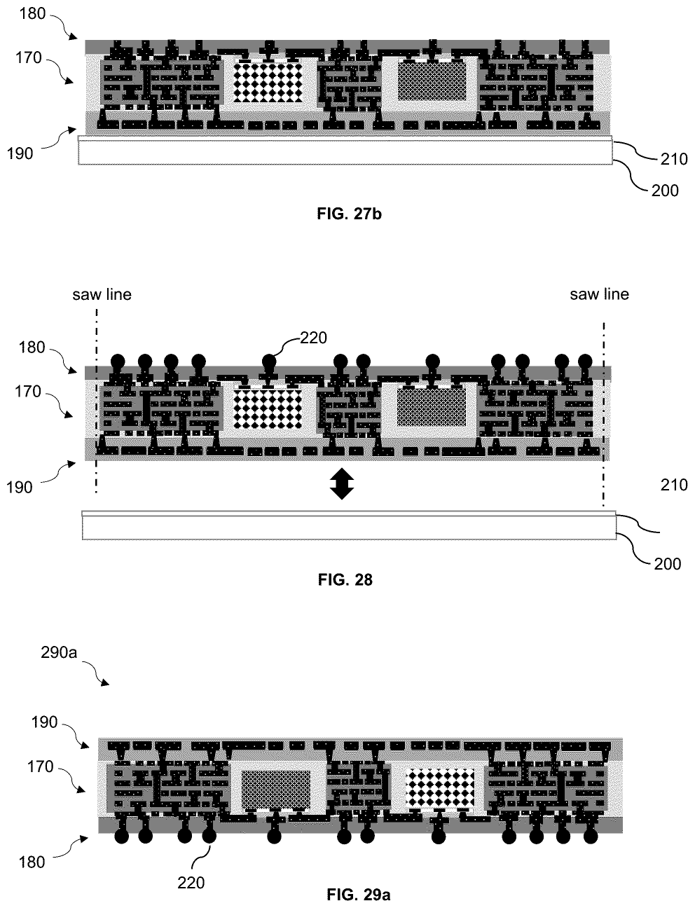

FIGS. 27a & 27b illustrate Step S17 of the panel-level method S10 for MCM. Similar to FIG. 10a, FIG. 27a shows that the pre-vias 156 of the first semiconductor die 150a and the second semiconductor die 150b are filled with conductive materials into the filled vias 158. If the pre-vias 156 has been filled into the filled vias 158 before bonding the first semiconductor die 150a and the second semiconductor die 150b onto the first carrier 130 and the first heat release tape 140, then the FIG. 27a can be skipped. Similar to FIG. 10b, FIG. 27b shows that the front build-up layer 180 are formed as described above (without showing the stud cavity 188 in FIG. 27c).

FIG. 28 illustrates Step S18 and Step 19 of the panel-level method S10 for MCM. Similar to FIG. 11, the external connection layer 220 such as solder balls is formed onto the front build-up layer 180; and then similar to FIG. 12, the reconstructed panel 170 with the front build-up layer 180 and the back build-up layer 190 are separated from the second carrier 200 and the second heat release tape 210; and then singulated into individual semiconductor packages 290 with the first semiconductor die 150a and the second semiconductor die 150b (MCM).

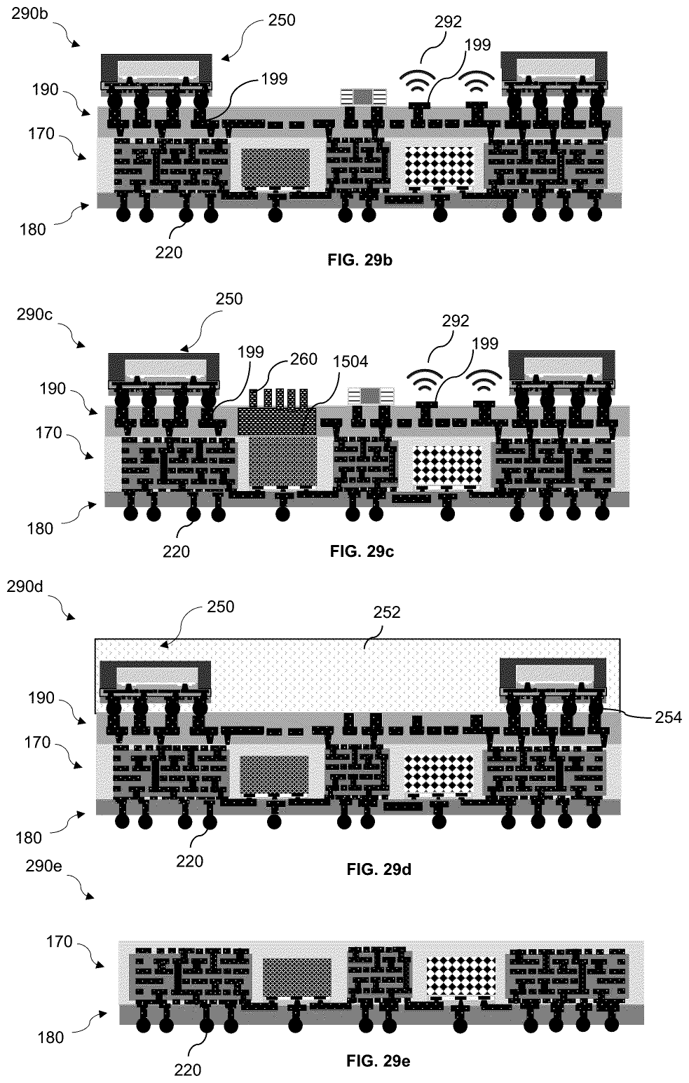

FIGS. 29a & 29e illustrate various embodiments of the semiconductor packages (MCM) 290 obtained from the panel-level method S10. FIG. 29a shows a first semiconductor package (MCM) 290a as singulated from FIG. 28 including the reconstructed panel 170 with the front build-up layer 180 and the back build-up layer 190. FIG. 29b shows a second semiconductor package (MCM) 290b where the passive electrical devices 240 and the top semiconductor packages 250 are mounted on the front build-up layer 180 and electrically coupled to the back studs 199 of the back build-up layer 190 as described above. In addition, an antenna 292 may be also mounted on the back studs 199 of the back build-up layer 190. FIG. 29c shows a third semiconductor package (MCM) 290c where the heat sink 260 is mounted onto and in direct contact with the back surface 1504 of the semiconductor die 150 for enhancing heat dissipation. FIG. 29d shows a fourth semiconductor package (MCM) 290d where the POP configuration is formed with the top semiconductor package 250 mounted onto the back build-up layer 190. In addition, the package dielectric layer 252 can be also used as the underfill as described above. FIG. 29c shows a fifth semiconductor package (MCM) 290e including the reconstructed panel 170 with the front build-up layer 180 but without the back build-up layer 190.

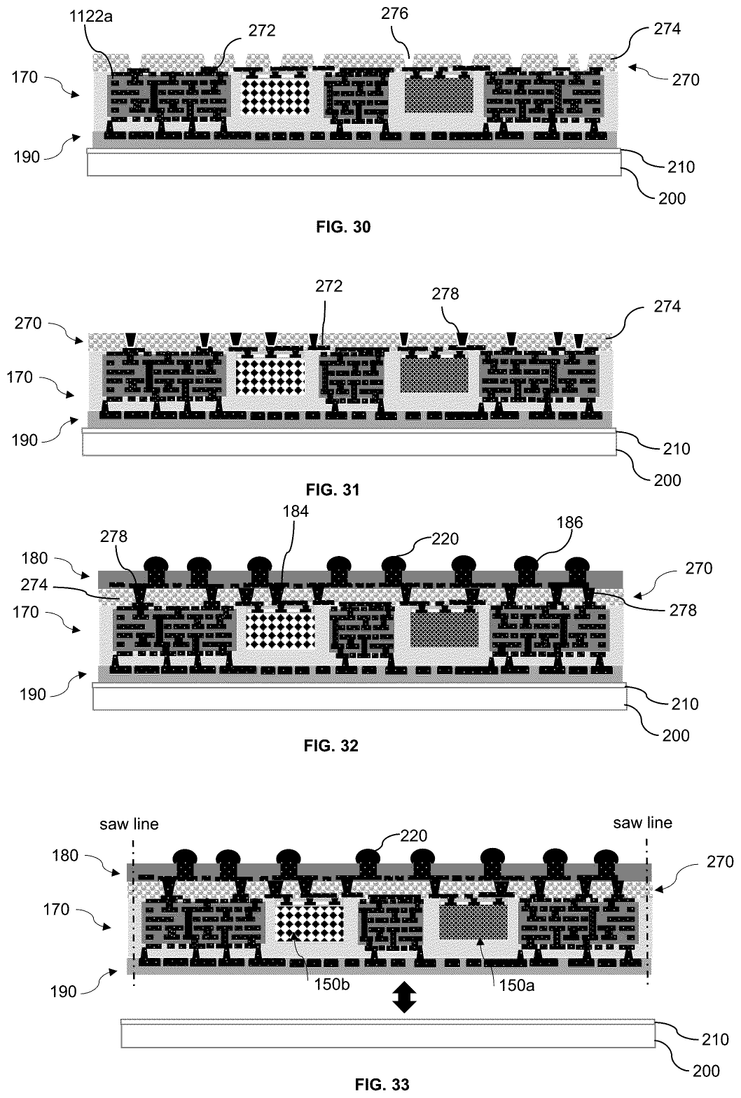

Similar FIGS. 14 to 17, FIGS. 30 to 33 illustrate a variation to the panel-level method S10 for MCM by further including the additional build-up layer 270. FIG. 30 shows a cross-sectional view that the additional build-up layer 270 includes the additional traces 272 electrically coupled to the first routing layer 1122a of the first conductive portion 110a; the additional dielectric layer 274 for encapsulating the additional traces 272, and the additional vias 276 for exposing portions of the additional traces 272 from the additional dielectric layer 274. FIG. 31 shows that the additional vias 276 are filled with conducting materials to form the additional filled vias 278 electrically coupled to the additional traces 272. FIG. 32 shows that the front build-up layer 180 is formed on the additional build-up layer 270 with the front traces 184 electrically coupled to the additional filled vias 278; and then the external connection layer 220 such as solder balls is formed and electrically coupled to the front studs 186 of the front build-up layer 180 as described above. FIG. 33 shows that the reconstructed panel 170 with the front build-up layer 180, the back build-up layer 190 and the additional build-up layer 270 is first separated from the second carrier 200 and second heat release tape 210; and then singulated along the saw lines into individual semiconductor packages 280 with the first semiconductor die 150a and the second semiconductor die 150b (MCM).

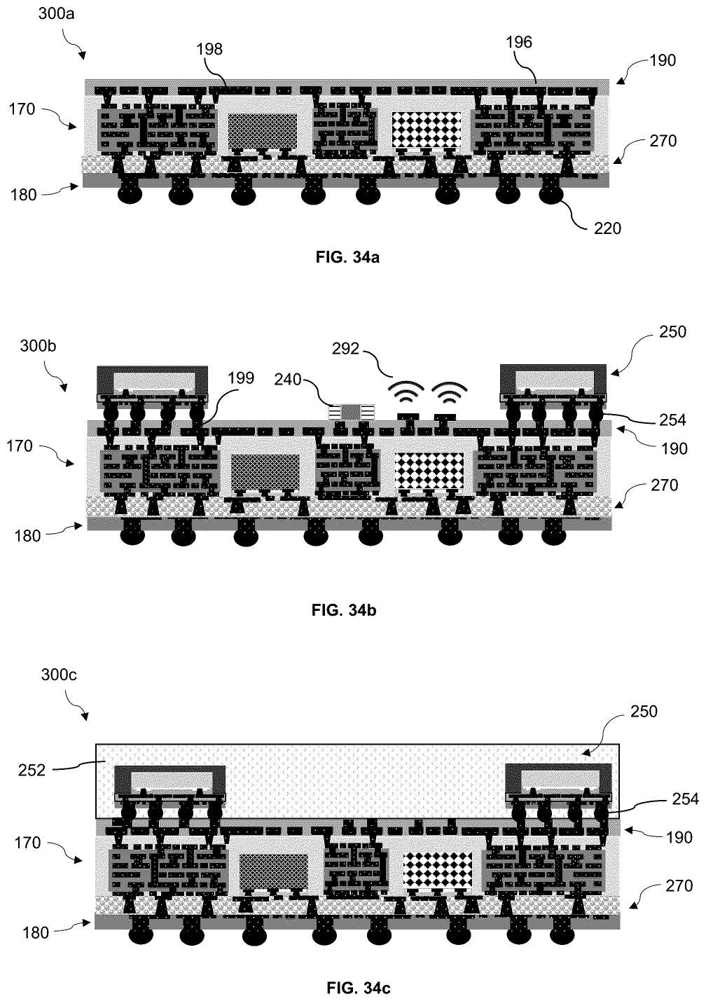

FIGS. 34a to 34c illustrate various embodiments of the semiconductor packages (MCM) 300 obtained from the variation in FIGS. 30 to 33. FIG. 34a shows a cross-sectional view of a first semiconductor package (MCM) 300a following the FIG. 33. In the back build-up layer 190, the back traces 198 is encapsulated in the back dielectric layer 196. FIG. 34b shows a cross-sectional view of a second semiconductor package (MCM) 300b where the passive electrical devices 240, the top semiconductor package 250 and the antenna 292 are mounted on the back studs 199 of the back build-up layer 190. FIG. 34c shows a cross-sectional view of a third semiconductor package (MCM) 300c where the POP configuration is formed with the top semiconductor package 250 mounted onto the back build-up layer 190. In addition, the package dielectric layer 252 can be also used as the underfill as described above.

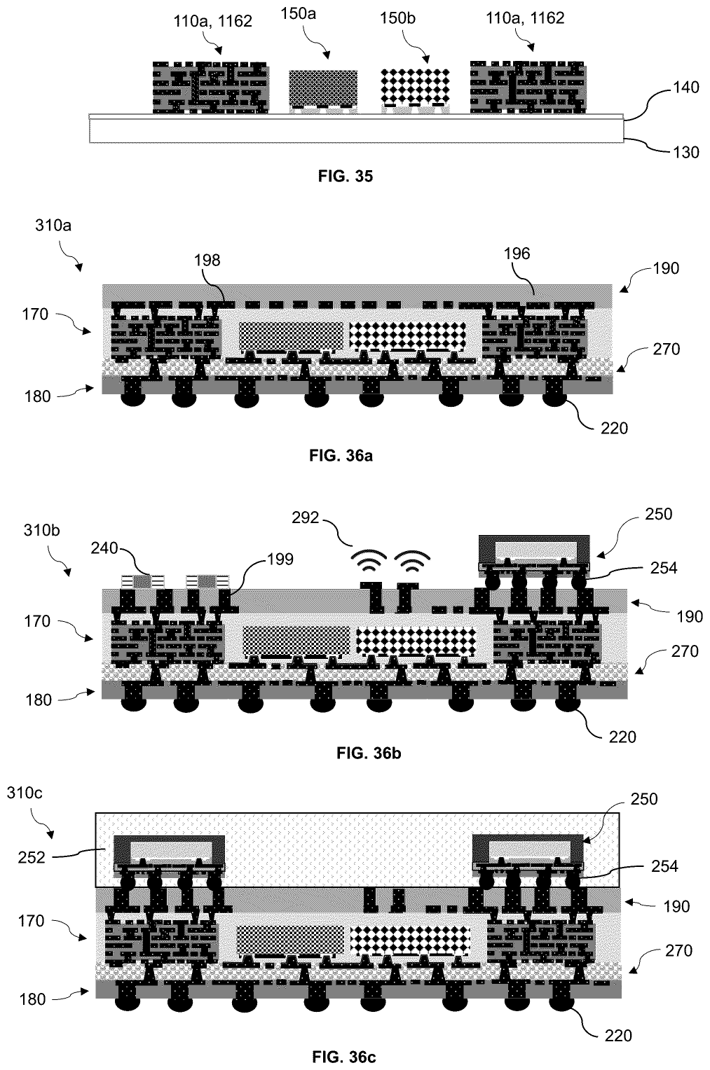

FIG. 35 illustrates another variation to the panel-level method S10 for MCM. Similar to the FIGS. 19c, 20c and 21c, the first semiconductor die 150a and the second semiconductor die 150b are bonded on the first carrier 130, but only one or more of the first pre-made conductive units 1162 are adopted for the first conductive portion 110a (as the pre-made conductive unit 116) around but not between the first semiconductor die 150a and the second semiconductor die 150b. Since the first semiconductor die 150a and the second semiconductor die 150b are adjacent to each other, communications between them would become more rapid. Then subsequent processes to this variation are the same as described above and therefore skipped for simple illustration. FIGS. 36a to 36c illustrate various embodiment of the semiconductor packages (MCM) 310 obtained from the variation in FIG. 35. FIG. 36a shows a cross-sectional view of a first semiconductor package (MCM) 310a. Similar to the first semiconductor package (MCM) 300a, the back traces 198 of the back build-up layer 190 is encapsulated in the back dielectric layer 196. FIG. 36b shows a cross-sectional view of a second semiconductor package (MCM) 310a. Similar to the second semiconductor package (MCM) 300b, the passive electrical devices 240, the top semiconductor package 250 and the antenna 292 are mounted on the back studs 199 of the back build-up layer 190. FIG. 36c shows a cross-sectional view of a third semiconductor package (MCM) 310c. Similar to the third semiconductor package (MCM) 300c, the POP configuration is formed with the top semiconductor package 250 mounted onto the back build-up layer 190. In addition, the package dielectric layer 252 can be also used as the underfill as described above.

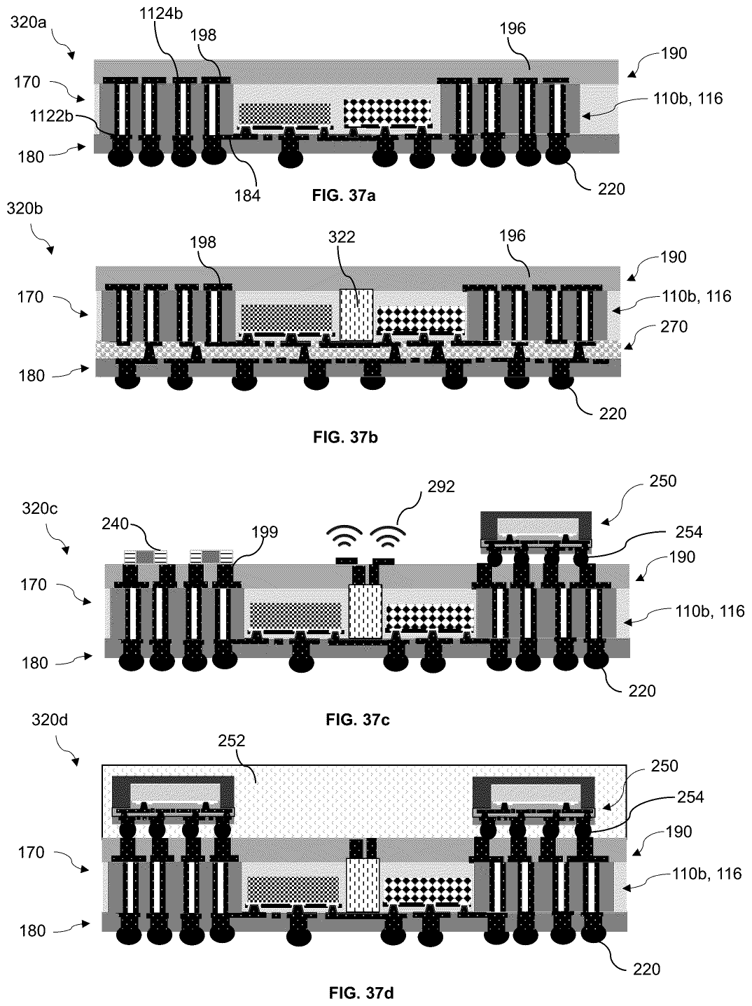

FIGS. 37a to 37d illustrate various embodiment of the semiconductor packages (MCM) 320 obtained from the panel-level method S10. FIG. 37a shows a cross-sectional view of a first semiconductor package 320a similar to the semiconductor packages described above such as the semiconductor package 290a in FIG. 29a. However, the semiconductor package 320a adopts the second conductive portion 110b as the pre-made conductive unit 116, instead of the first conductive portion 110a for the semiconductor package 290a. Therefore, the through-via front surface 1122b and the through-via back surface 1124b of the second conductive portion 110b are electrically coupled to the back traces 198 of the back build-up layer 190 and the front traces 184 of the front build-up layer 180 respectively.

FIG. 37b shows a cross-sectional view of a second semiconductor package 320b which further includes the additional build-up layer 270 between the reconstructed panel 170 and the front build-up layer 180 as described above. In addition to the second conductive portion 110b, the semiconductor package 320b also includes one or more Copper columns 322 between the first semiconductor die 150a and the second semiconductor die 150b for electrical coupling. It is understood that other similar structures to the Copper columns 322 are also within the scope of the present application. FIG. 37c shows a cross-sectional view of a third semiconductor package 320c where the back studs 199, the passive electrical devices 240 and the top semiconductor packages 250 are mounted onto the back build-up layer 190; and electrically coupled to the back studs 199 of the back build-up layer 190. FIG. 37d shows a cross-sectional view of a fourth semiconductor package 320d where the POP configuration is formed with the top semiconductor package 250 mounted onto the back build-up layer 190. In addition, the package dielectric layer 252 can be also used as the underfill as described above.

For all the structure of the semiconductor packages (MCM) described above made from the panel-level method S10, including the semiconductor packages 290a to 290c, 300a to 300c, 310a to 310c, and 320a to 320d, the first and second semiconductor dies 150a, 150b and the pre-made conductive unit 116 (in the form of either the first conductive portion 110a or the second conducive portion 110b) are arranged in a side-by-side configuration and encapsulated inside the molding layer 160 and become components of the reconstructed panel 170 accordingly.

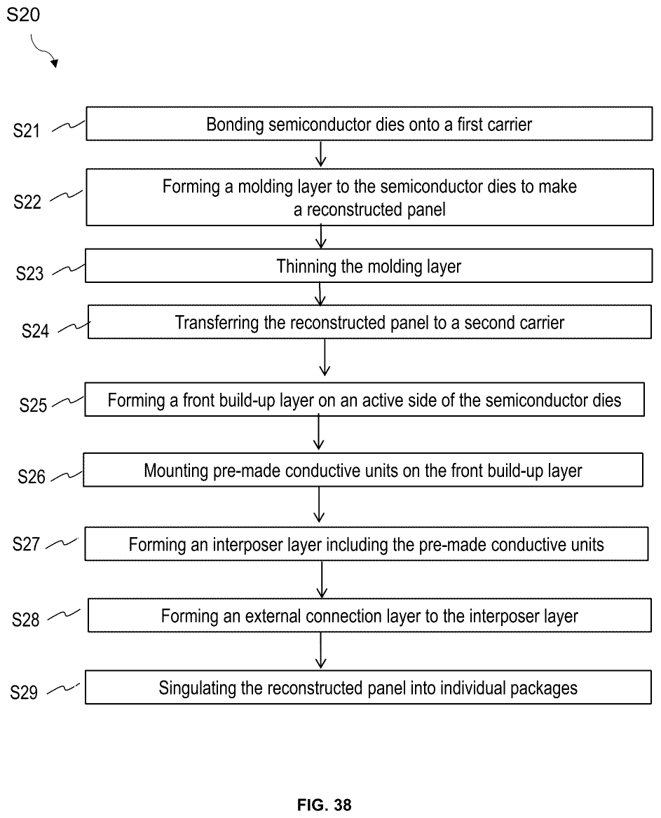

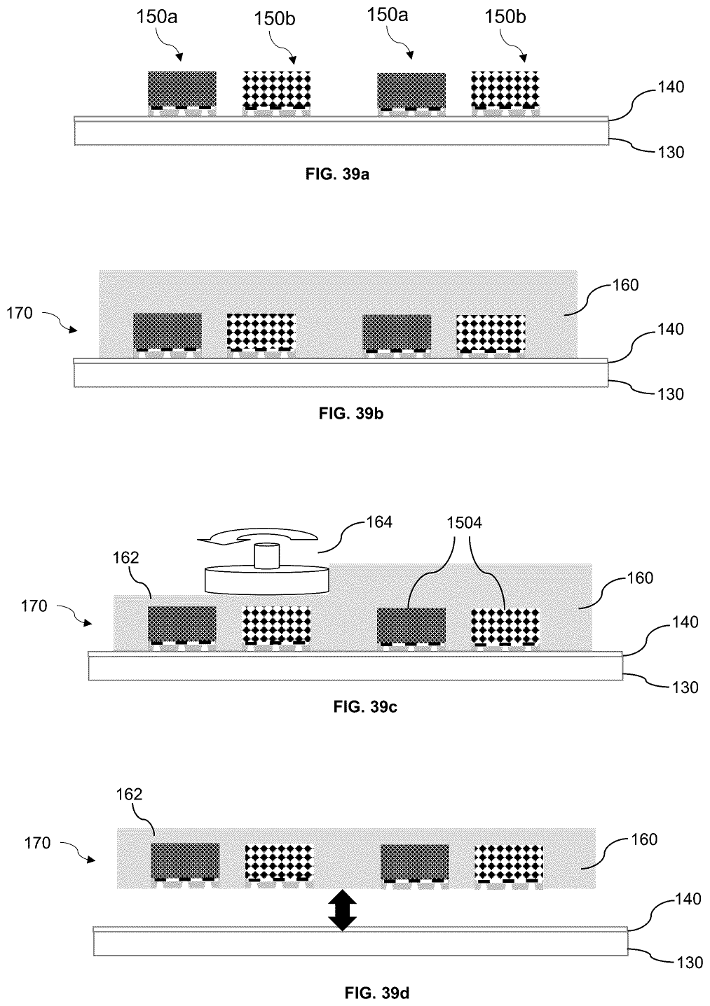

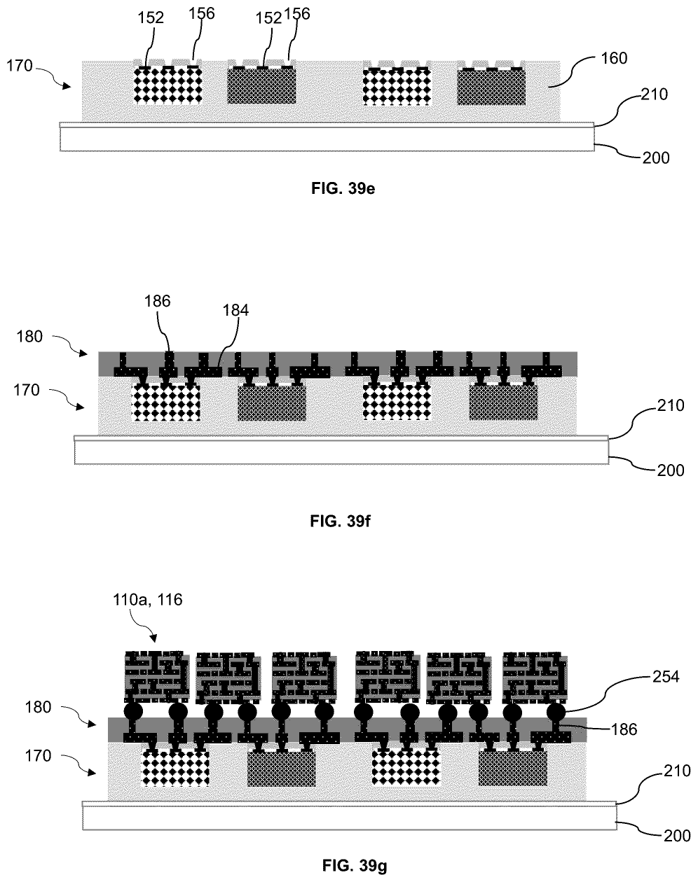

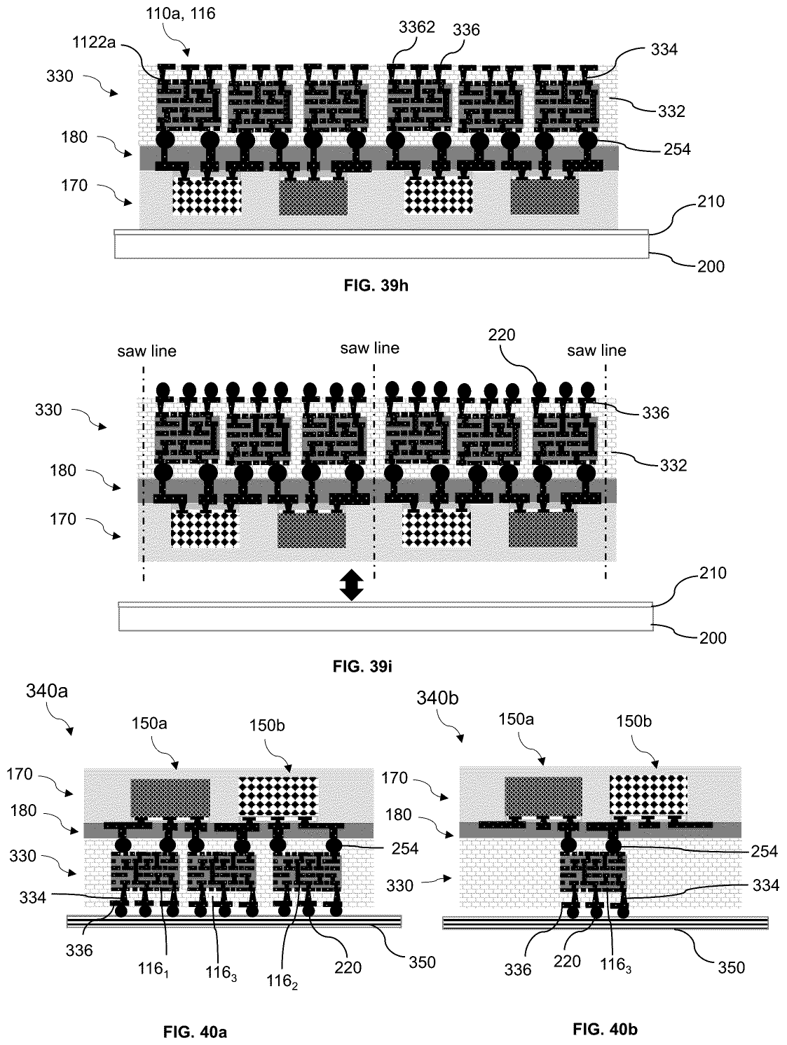

FIG. 38 illustrates a flow chart of another panel-level method S20 of making semiconductor packages (MCM) according to an exemplary embodiment of the present disclosure. The panel-level method S20 includes Steps S21 to S29. FIGS. 39a to 39i illustrate cross-sectional views of the panel-level method S20 accordingly.

FIG. 39a illustrates a first step S21 of the panel-level method S20, i.e., bonding the semiconductor dies 150 onto the first carrier 130 and maybe the first heat release tape 140. Only the first semiconductor die 150a and the second semiconductor die 150b are shown here, but it is understood that more semiconductor dies 150 could be bonded onto the first carrier 130. FIG. 39b illustrates a second step S22 of the panel-level method S20, i.e., forming the reconstructed panel 170 by applying the molding layer 160 for encapsulating the first semiconductor die 150a and the second semiconductor die 150b. FIG. 39c illustrates a third step S23 of the panel-level method S20, i.e., thinning the molding layer 160 with the grinding apparatus 164; and accordingly, the top portion 162 is left which still encapsulates the back surface 1504 of the first semiconductor die 150a and the second semiconductor die 150b.

FIG. 39d illustrates a first sub-step S242 of a fourth step S24 of the panel-level method S20, i.e., separating the reconstructed panel 170 from the first carrier 130 and the first heat release tape 140 at the elevated temperature; and then FIG. 39e illustrates a second sub-step S244 of the fourth step S24, i.e., mounting the reconstructed panel 170 to the second carrier 200 in a flip manner onto the second carrier 200 and maybe the second heat release tape 210; and accordingly, the contact pads 152 are exposed from the pre-vias 156 for the first semiconductor die 150a and the second semiconductor die 150b. As a result, the reconstructed panel 170 is transferred from the first carrier 130 to the second carrier 200. FIG. 39f illustrates a fifth step S25 of the panel-level method S20, i.e., forming the front build-up layer 180 onto the reconstructed panel 170; and the contact pads 152 is electrically coupled to the front traces 184 and the front studs 186 of the front build-up layer 180. FIG. 39g illustrates a sixth step S26 of the panel-level method S20, i.e., mounting the pre-made conductive unit 116 (in the form of the first conductive portion 110a shown here) onto the front build-up layer 180 with the internal connection layer 254 electrically coupled to the front studs 186 of the front build-up layer 180. The first conductive portions 110a are made by removing the insulating portion 120 from the molded interconnect substrate (MIS) 100a as described above. Alternatively, the pre-made conductive unit 116 may be the second conductive portion 110b which is made by removing the insulating portion 120 from the molded via substrate (MVS) 100b as described above. Of course, other forms of the pre-made conductive unit 116 are also within the scope of the present application. Alternative to the solder balls, the external connection layer 220 may also include surface finish for providing a very flat surface for Input/Output (I/O). The surface finish may be made of a single layer of metals such as Tin or a single layer of metal composites such as Nickel/Gold. Alternatively, the surface finish may be made of multiple layers. In some embodiments, the surface finish 298 is made of Electroless Nickel Immersion Gold (ENIG) which has a two-layer metallic surface finish with a first layer of Nickel using an electroless chemical reaction; and then a very thin layer of Gold plated onto the layer of Nickel. In other embodiments, the surface finish is made of Electroless Nickel Electroless Palladium Immersion Gold (ENEPIG) which is formed by deposition of electroless Nickel, followed by electroless palladium, and finally an immersion gold flash. The surface finish is chemically compatible with the I/O for improving stability of connection. The surface finish may have a thickness in a range of 1 to 10 micrometers (μm), preferably 1 to 5 micrometers (μm), or more preferably 1 to 3 micrometers (μm).

FIG. 39h illustrates a seventh step S27 of the panel-level method S20, i.e., forming an interposer layer 330 including interposer filled vias 334 electrically coupled to the first routing layer 1122a of the first conductive portion 110a, interposer traces 336 electrically coupled to the interposer filled vias 334, and an interposer dielectric layer 332 for encapsulating the internal connection layer 254, the first conductive portion 110a (including the first routing layer 1122a), the interposer filled vias 334 and the interposer traces 336; but a first interposer trace surface 3362 of the interposer traces 336 is exposed from the interposer dielectric layer 332. In addition, similar to the package dielectric layer 252, the interposer dielectric layer 332 can also act as the underfill for protecting the internal connection layer 254. Optionally, the interposer dielectric layer 332 has a filler size less than 20 micrometers (μm); and preferably, the filler size of the interposer dielectric layer 332 is in a range of 10 to 20 micrometers (μm). FIG. 39i illustrates an eighth step S28 of the panel-level method S20, i.e., forming the external connection layer 220 (such as solder balls shown here) electrically coupled to the interposer traces 336, as well as a ninth step S29 of the panel-level method S20, i.e., separating the reconstructed panel 170 with the front build-up layer 180 and the interposer layer 330 from the second carrier 200 and the second heat release tape 210 at the elevated temperature and singulating the reconstructed panel 170 with the front build-up layer 180 and the interposer layer 330 into individual semiconductor packages (MCM) 340.

FIGS. 40a & 40b illustrate two embodiments of the semiconductor packages (MCM) obtained from the FIGS. 39a to 39i. FIG. 40a shows a cross-sectional view of a first semiconductor package (MCM) 340a mounted on an external device 350 such as PCB. The first semiconductor die 150a and the second semiconductor die 150b are electrically led out through the front build-up layer 180, and the internal connection layer 254, the pre-made conductive unit 116 (in the form of the first conductive portion 110a), the interposer filled vias 334 and the interposer traces 336 of the interposer layer 330, the external connection layer 220, and finally to the external device 350. FIG. 40a further shows a first piece 1161 of the pre-made conductive unit 116 for electrically coupling the first semiconductor die 150a to the external device 350, a second piece 1162 of the pre-made conductive unit 116 for electrically coupling the second semiconductor die 150b to the external device 350, and a third piece 1163 of the pre-made conductive unit 116 for internal electrical coupling between the first semiconductor die 150a and the second semiconductor die 150b which would be also further led out to the external device 350. FIG. 40b shows a cross-sectional view of a second semiconductor package (MCM) 340b similar to the semiconductor package 340a. However, the semiconductor package 340b has only the third piece 1163 of the pre-made conductive unit 116 for internal electrically coupling between the first semiconductor die 150a and the second semiconductor die 150b which would be also further led out to the external device 350. Although not shown, it is understood that the pre-made conductive unit 116 can also be in the form of second conductive portion 110b; and other forms of the pre-made conductive unit 116 are also within the scope of the present application.

For all the structure of the semiconductor packages (MCM) described for the panel-level method S20, including the semiconductor packages 340a, 340b, the first and second semiconductor dies 150a, 150b and the pre-made conductive unit 116 (in the form of either the first conductive portion 110a or the second conducive portion 110b) are arranged in a vertical configuration. Accordingly, the first and second semiconductor dies 150a, 150b are encapsulated inside the molding layer 160 and become components of the reconstructed panel 170; while the pre-made conductive unit 116 is encapsulated inside the additional dielectric layer 274 and become a component of the additional build-up layer 270.

In the application, unless specified otherwise, the terms “comprising”, “comprise”, and grammatical variants thereof, intended to represent “open” or “inclusive” language such that they include recited elements but also permit inclusion of additional, non-explicitly recited elements.

As used herein, the term “about”, in the context of concentrations of components of the formulations, typically means+/−5% of the stated value, more typically +/−4% of the stated value, more typically +/−3% of the stated value, more typically, +/−2% of the stated value, even more typically +/−1% of the stated value, and even more typically +/−0.5% of the stated value.

Throughout this disclosure, certain embodiments may be disclosed in a range format. The description in range format is merely for convenience and brevity and should not be construed as an inflexible limitation on the scope of the disclosed ranges. Accordingly, the description of a range should be considered to have specifically disclosed all the possible sub-ranges as well as individual numerical values within that range. For example, description of a range such as from 1 to 6 should be considered to have specifically disclosed sub-ranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

It will be apparent that various other modifications and adaptations of the application will be apparent to the person skilled in the art after reading the foregoing disclosure without departing from the spirit and scope of the application and it is intended that all such modifications and adaptations come within the scope of the appended claims.

Reference Numerals

| | |
|---|---|
| 100 | molded conductive substrate |
| 100a | molded interconnect substrate (MIS) |
| 100b | molded via substrate (MVS) |
| 110 | conductive portion |
| 110a | first conductive portion |
| 110b | second conductive portion |
| 112 | conductive component |
| 112a | routing layers |
| 1122a | first routing layer of the routing layers |
| 1123a | first side of the first routing layer |
| 1124a | second routing layer of the routing layers |
| 1125a | second side of the second routing layer |
| 112b | conductive through-vias |
| 1122b | through-via front surface of the conductive |
| | through-vias |
| 1124b | through-via back surface of the conductive |
| | through-vias |
| 1126 | hollow vias of the conductive through-vias |
| 1128 | sidewall of the conductive through-vias |
| 114a/114b | insulating component |
| 1142a/1142b | first surface of the insulating component |
| 1144a/1144b | second surface of the insulating component |
| 116 | pre-made conductive unit |
| 1162 | first pre-made conductive unit |
| 1164 | second pre-made conductive unit |
| 116₁ | first piece of the pre-made conductive unit |
| 116₂ | second piece of the pre-made conductive unit |
| 116₃ | third piece of the pre-made conductive unit |
| 118 | gap |
| 1182 | first gap |
| 1184 | second gap |
| 120 | insulating portion |
| 130 | first carrier |
| 132 | die bonding regions |
| 133 | primary markings |
| 134 | unit bonding regions |
| 135 | secondary markings |
| 136 | fiducials |
| 140 | first heat release tape |
| 150 | semiconductor die |
| 150a | first semiconductor die |
| 150b | second semiconductor die |
| 1502 | active surface of the semiconductor die |
| 1504 | back surface of the semiconductor die |
| 152 | contact pad |
| 154 | protective layer |
| 156 | pre-vias |
| 158 | filled vias |
| 160 | molding layer |
| 162 | top portion of the molding layer |
| 164 | grinding apparatus |
| 170 | reconstructed panel |
| 180 | front build-up layer |
| 182 | front dielectric layer of the front build-up layer |
| 1822 | first dielectric surface of the front dielectric layer |
| 184 | front traces of the front build-up layer |
| 186 | front studs of the front build-up layer |
| 1862 | first stud surface of the front studs |
| 188 | stud cavity |
| 190 | back build-up layer |
| 192 | back vias of the back build-up layer |
| 194 | back filled vias of the back build-up layer |
| 1942 | first via surface of the back filled vias |
| 1944 | second via surface of the back filled vias |
| 196 | back dielectric layer of the back build-up layer |
| 198 | back traces of the back build-up layer |
| 199 | back stud of the back build-up layer |
| 1992 | second stud surface of the back stud |
| 200 | second carrier |
| 210 | second heat release tape |
| 220 | external connection layer (solder balls) |
| 230 | semiconductor package (SCM) |
| 240 | passive electrical devices |
| 250 | top semiconductor package |
| 252 | package dielectric layer |
| 254 | internal connection layer (solder ball) |
| 256 | internal space |
| 260 | heat sink |
| 270 | additional build-up layer |
| 272 | additional traces of the additional build-up layer |
| 274 | additional dielectric layer of the additional |
| | build-up layer |
| 276 | additional vias of the additional build-up layer |
| 278 | additional filled vias of the additional |
| | build-up layer |
| 280 | semiconductor package (SCM) |
| 290 | semiconductor package (MCM) |
| 292 | antenna |
| 300, 310, 320, 340 | semiconductor package (MCM) |
| 322 | Copper column |
| 330 | interposer layer |
| 332 | interposer dielectric layer of the interposer layer |
| 334 | interposer filled vias of the interposer layer |
| 336 | interposer traces of the interposer layer |
| 3362 | first interposer trace surface of the interposer traces |
| 350 | extenal device (PCB) |

What is claimed is:

1. A panel-level method of forming a semiconductor package, comprising:
providing at least one semiconductor die and a plurality of pre-made conductive units onto a first carrier to their pre-determined positions respectively, wherein the pre-made conductive units are prepared from a molded conductive substrate;
forming a molding layer for encapsulating the at least one semiconductor die and the plurality of pre-made conductive units to constitute a reconstructed panel;
transferring the reconstructed panel onto a second carrier;
forming a front build-up layer on an active surface of the at least one semiconductor die;
forming an external connection layer electrically coupled to the front build-up layer; and
singulating the reconstructed panel, the front build-up layer and the external connection into the semiconductor package; and,
wherein the at least one semiconductor die and the plurality of pre-made conductive units are configured to be electrically coupled to the external connection layer through the front build-up layer.

2. The method of claim 1, wherein providing the at least one semiconductor die and the plurality of pre-made conductive units comprises:
placing the molded conductive substrate onto the first carrier; and
removing insulating portions from the molded conductive substrate, wherein conductive portions of the molded conductive substrate are left on the first carrier as the pre-made conductive units individually.

3. The method of claim 1, wherein providing the at least one semiconductor die and the plurality of pre-made conductive units comprises:
removing insulating portions from the molded conductive substrate, wherein conductive portions of the molded conductive substrate are left as the pre-made conductive units individually; and
bonding the pre-made conductive units onto the first carrier to their pre-determined positions respectively.

4. The method of claim 1, wherein the pre-made conductive unit comprises a plurality of interconnected routing layers, and a first routing layer of the plurality of interconnected routing layers is configured to be electrically coupled to the front build-up layer.

5. The method of claim 1, wherein the pre-made conductive unit comprises at least one conductive through-via, and a through-via front surface of the at least one conductive through-via is configured to be electrically coupled to the front build-up layer.

6. The method of claim 1, further comprising:
forming a back build-up layer on and electrically coupled to the plurality of pre-made conductive units, wherein the back build-up layer is opposed to the front build-up layer.

7. A panel-level method of forming a semiconductor package, comprising:
bonding a plurality of semiconductor dies onto a first carrier to their pre-determined positions respectively;
forming a molding layer for encapsulating the plurality of semiconductor dies to constitute a reconstructed panel;
transferring the reconstructed panel onto a second carrier;
forming a front build-up layer on an active surface of the plurality of semiconductor dies;
forming an interposer layer onto the front build-up layer, wherein the interposer layer comprises pre-made conductive units; and the pre-made conductive units are prepared from a molded conductive substrate;
forming an external connection layer to the interposer layer; and
singulating the reconstructed panel, the front build-up layer, the interposer layer and the external connection layer into the semiconductor package; and,
wherein the semiconductor dies are configured to be electrically coupled to the external connection layer through the front build-up layer and the interposer layer.

8. The method of claim 7, further comprising:
providing the plurality of pre-made conductive units by removing insulating portions of the molded conductive substrate, wherein conductive portions of the molded conductive substrate are left as the pre-made conductive units individually.

9. The method of claim 7, wherein the pre-made conductive unit comprises a plurality of interconnected routing layers, and a first routing layer of the plurality of interconnected routing layers is configured to be electrically coupled to the front build-up layer.

10. The method of claim 7, wherein the pre-made conductive unit comprises at least one conductive through-via, and a through-via front surface the at least one conductive through-via is configured to be electrically coupled to the front build-up layer.

11. A semiconductor package with at least one pre-made conductive unit, comprising:
at least one semiconductor die;
a molding layer for encapsulating the at least one semiconductor die;
at least one pre-made conductive unit prepared from a molded conductive substrate;
a front build-up layer electrically coupled to the at least one semiconductor die and the at least one pre-made conductive unit; and
an external connection layer electrically coupled to the front build-up layer.

12. The semiconductor package of claim 11, further comprising:
a back build-up layer on the pre-made conductive units, wherein the back build-up layer is opposed to the front build-up layer.

13. The semiconductor package of claim 11, wherein the at least one pre-made conductive unit comprises a plurality of interconnected routing layers, and a first routing layer of the plurality of interconnected routing layers is configured to be electrically coupled to the front build-up layer.

14. The semiconductor package of claim 13, wherein the at least one pre-made conductive unit comprise an insulating component, and the first routing layer is exposed from the insulating component.

15. The semiconductor package of claim 14, wherein the at least one conductive through-via of the pre-made conductive unit is formed by filling a hollow via in an insulating component of the pre-made conductive unit with any conductive materials.

16. The semiconductor package of claim 11, wherein the at least one pre-made conductive unit comprises at least one conductive through-via, and a through-via front surface of the conductive through-via is configured to be electrically coupled to the front build-up layer.

17. The semiconductor package of claim 11, further comprising:
an additional build-up layer between the at least one semiconductor die and the front build-up layer.

18. The semiconductor package of claim 11, wherein the at least one semiconductor die comprises a first semiconductor die and a second semiconductor die which are electrically coupled through the at least one pre-made conductive unit.

19. The semiconductor package of claim 18, wherein the at least one pre-made conductive unit is encapsulated in the molding layer in a side-by-side configuration with the first semiconductor die and the second semiconductor die.

20. The semiconductor package of claim 18, wherein the at least one pre-made conductive unit is encapsulated in a dielectric layer in a vertical configuration with the first semiconductor die and the second semiconductor die.
